(19) United States
(12) Patent Application Publication
(10) Pub. No.: US 2013/0224937 A1
(43) Pub. Date: Aug. 29, 2013

(54) METHOD FOR MANUFACTURING SEMICONDUCTOR DEVICE

(71) Applicants: Hiroki Tanimura, Osaka-shi (JP); Yoshiyuki Nasuno, Osaka-shi (JP); Kuriyo Shimada, Osaka-shi (JP)

(72) Inventors: Hiroki Tanimura, Osaka-shi (JP); Yoshiyuki Nasuno, Osaka-shi (JP); Kuriyo Shimada, Osaka-shi (JP)

(73) Assignee: SHARP KABUSHIKI KAISHA, Osaka-shi, Osaka (JP)

(21) Appl. No.: 13/883,655

(22) PCT Filed: Nov. 4, 2011
(86) PCT No.: PCT/JP2011/075434

§ 371 Date: May 6, 2013

(30) Foreign Application Priority Data
Nov. 16, 2010 (JP) 2010-255844

(51) Int. Cl. H01L 21/02

(52) U.S. Cl. CPC H01L 21/0262
USPC 438/507

(57) ABSTRACT

Semiconductor layer forming gas is introduced into a reaction chamber, and the gas generates a plasma discharge, so that a semiconductor layer is formed. In addition to the gas, impurity gas is introduced into the chamber, and first conductivity type layer forming gas including the semiconductor layer forming gas and the impurity gas generates a plasma discharge, so that a first conductivity type layer of a first conductivity type is formed so as to cover the semiconductor layer. In the step of forming the first conductivity type layer, a composition set value of gas supplied to the chamber is shifted from a composition of the semiconductor layer forming gas to a composition of the first conductivity type layer forming gas in a state where a pressure in the chamber is not reduced to ultimate vacuum even after a plasma discharge processing for forming the semiconductor layer is terminated.

### TECHNICAL FIELD

The present invention relates to a method for manufacturing a semiconductor device.

### BACKGROUND ART

Japanese Patent Laying-Open No. 04-266067 (PTD 1) and Japanese Patent Laying-Open No. 2009-004702 (PTD 2) disclose methods for manufacturing a photoelectric conversion device. The methods are examples of a method for manufacturing a semiconductor device by depositing a conductivity type layer (n-type layer or p-type layer) so as to cover a semiconductor layer (i-type layer). According to the methods disclosed in PTD 1 and PTD 2, after a semiconductor layer is deposited, the interior of a reaction chamber is highly evacuated to attain a vacuum degree of less than or equal to 10⁻⁶ Torr or approximately 0.001 Pa. Thereafter, predetermined impurity gas is introduced into the reaction chamber to deposit a conductivity type layer on a semiconductor layer.

Japanese Patent Laying-Open No. 2007-059560 (PTD 3) discloses a method for manufacturing a thin film semiconductor device. The method is an example of a method for manufacturing a semiconductor device by depositing a conductivity type layer (n⁺ a-Si layer) so as to cover a semiconductor layer (amorphous silicon layer). PTD 3 does not particularly disclose a specific method for forming an n⁺ a-Si layer after forming an amorphous silicon layer.

### CITATION LIST

### Patent Document

PTD 1: Japanese Patent Laying-Open No. 04-266067
PTD 2: Japanese Patent Laying-Open No. 2009-004702
PTD 3: Japanese Patent Laying-Open No. 2007-059560

### SUMMARY OF INVENTION

### Technical Problem

According to the manufacturing methods disclosed in PTD 1 and PTD 2, a reaction chamber is highly evacuated after forming a semiconductor layer, and then a conductivity type layer is formed after replacing gas in the reaction chamber. According to this method, energy and time for once highly evacuating the reaction chamber are required. Therefore, productivity is lowered.

An object of the present invention is to provide a method for manufacturing a semiconductor device by using a plasma CVD (Chemical Vapor Deposition) method to deposit a conductivity type layer so as to cover a semiconductor layer, allowing productivity exhibited after formation of a semiconductor layer and until formation of a conductivity type layer to be improved.

### Solution to Problem

A method for manufacturing a semiconductor device in accordance with a first aspect of the present invention is a method for manufacturing a semiconductor device by using a plasma CVD method to deposit a conductivity type layer so as to cover a semiconductor layer. The method includes the steps of: forming the semiconductor layer on a predetermined layer by introducing semiconductor layer forming gas into a reaction chamber and allowing the semiconductor layer forming gas to generate a plasma discharge; and forming a first conductivity type layer of a first conductivity type so as to cover the semiconductor layer by introducing impurity gas in addition to the semiconductor layer forming gas into the reaction chamber and allowing first conductivity type layer forming gas including the semiconductor layer forming gas and the impurity gas to generate a plasma discharge. In the step of forming the first conductivity type layer, a composition set value of gas supplied to the reaction chamber is shifted from a composition of the semiconductor layer forming gas to a composition of the first conductivity type layer forming gas in a state where a pressure in the reaction chamber is not reduced to ultimate vacuum even after a plasma discharge processing for forming the semiconductor layer is terminated.

According to a method for manufacturing a semiconductor device in accordance with a second aspect of the present invention, in the step of forming the first conductivity type layer in the method for manufacturing a semiconductor device in accordance with the first aspect, the impurity gas is introduced into the reaction chamber in a state where introduction of the semiconductor layer forming gas into the reaction chamber is not stopped even after the plasma discharge processing for forming the semiconductor layer is terminated.

According to a method for manufacturing a semiconductor device in accordance with a third aspect of the present invention, in the method for manufacturing a semiconductor device in accordance with the first or second aspect of the present invention, the first conductivity type layer includes a lower first conductivity type layer of a first conductivity type and an upper first conductivity type layer of the first conductivity type, and the impurity gas includes first impurity gas for forming the lower first conductivity type layer and second impurity gas for forming the upper first conductivity type layer. The step of forming the first conductivity type layer includes the steps of: forming the lower first conductivity type layer so as to cover the semiconductor layer by introducing the first impurity gas in addition to the semiconductor layer forming gas into the reaction chamber and allowing lower first conductivity type layer forming gas including the semiconductor layer forming gas and the first impurity gas to generate a plasma discharge; and forming the upper first conductivity type layer so as to cover the lower first conductivity type layer by introducing the second impurity gas in addition to the semiconductor layer forming gas and the first impurity gas into the reaction chamber and allowing upper first conductivity type layer forming gas including the semiconductor layer forming gas, the first impurity gas, and the second impurity gas to generate a plasma discharge. In the step of forming the upper first conductivity type layer, a composition set value of gas supplied to the reaction chamber is shifted from a composition of the lower first conductivity type layer forming gas to a composition of the second impurity gas in a state where a pressure in the reaction chamber is not reduced to ultimate vacuum even after the plasma discharge processing for forming the lower first conductivity type layer is terminated.

According to a method for manufacturing a semiconductor device in accordance with a fourth aspect of the present invention, in the method for manufacturing a semiconductor device in accordance with the first or second aspects of the present invention, the first conductivity type layer includes a lower first conductivity type layer of a first conductivity type and an upper first conductivity type layer of the first conductivity type. The step of forming the first conductivity type layer includes the steps of: forming the lower first conductivity type layer so as to cover the semiconductor layer by introducing the impurity gas in addition to the semiconductor layer forming gas into the reaction chamber for a predetermined period of time and allowing lower first conductivity type layer forming gas including the semiconductor layer forming gas and the impurity gas to generate a plasma discharge; and forming the upper first conductivity type layer so as to cover the lower first conductivity type layer by allowing upper first conductivity type layer forming gas including the impurity gas and the semiconductor layer forming gas, with an introduction amount ratio changed by modifying an introduction amount ratio of the impurity gas relative to an introduction amount of the semiconductor layer forming gas after forming the lower first conductivity type layer, to generate a plasma discharge. In the step of forming the upper first conductivity type layer, a composition set value of gas supplied to the reaction chamber is shifted from a composition of the lower first conductivity type layer forming gas to a composition of the upper first conductivity type layer forming gas in a state where a pressure in the reaction chamber is not reduced to ultimate vacuum even after a plasma discharge processing for forming the lower first conductivity type layer is terminated.

According to a method for manufacturing a semiconductor device in accordance with a fifth aspect of the present invention, in a method for manufacturing a semiconductor device in accordance with any one of the first to fourth aspects, the semiconductor layer includes a lower semiconductor layer and an upper semiconductor layer, and the semiconductor layer forming gas includes first semiconductor layer forming gas for forming the lower semiconductor layer and second semiconductor layer forming gas for forming the upper semiconductor layer, and the step of forming the semiconductor layer includes the steps of forming the lower semiconductor layer on the predetermined layer by introducing the first semiconductor layer forming gas into the reaction chamber and allowing the first semiconductor layer forming gas to generate a plasma discharge, and forming the upper semiconductor layer so as to cover the lower semiconductor layer by introducing the second semiconductor layer forming gas in addition to the first semiconductor layer forming gas into the reaction chamber and allowing upper semiconductor layer forming gas including the first semiconductor layer forming gas and the second semiconductor layer forming gas to generate a plasma discharge. In the step of forming the upper semiconductor layer, a composition set value of gas supplied to the reaction chamber is shifted from a composition of the first semiconductor layer forming gas to a composition of the upper semiconductor layer forming gas in a state where a pressure in the reaction chamber is not reduced to ultimate vacuum even after a plasma discharge processing for forming the lower semiconductor layer is terminated.

According to a method for manufacturing a semiconductor device in accordance with a sixth aspect of the present invention, in the method for manufacturing a semiconductor device in accordance with any one of the first to fourth aspects of the present invention, the semiconductor layer includes a lower semiconductor layer and an upper semiconductor layer, and the step of forming the semiconductor layer includes the steps of: forming the lower semiconductor layer on the predetermined layer by introducing the semiconductor layer forming gas into the reaction chamber for another predetermined period of time and allowing the semiconductor layer forming gas to generate a plasma discharge; and forming the upper semiconductor layer so as to cover the lower semiconductor layer by allowing the semiconductor layer forming gas, with an introduction amount changed by modifying an introduction amount of the semiconductor layer forming gas after forming the lower semiconductor layer, to generate a plasma discharge. In the step of forming the upper semiconductor layer, a composition set value of gas supplied to the reaction chamber is shifted from a composition of the semiconductor layer forming gas for forming the lower semiconductor layer to a composition of the semiconductor layer forming gas for forming the upper semiconductor layer in a state where a pressure in the reaction chamber is not reduced to ultimate vacuum even after a plasma discharge processing for forming the lower semiconductor layer is terminated.

According to a method for manufacturing a semiconductor device in accordance with a seventh aspect of the present invention, in the method for manufacturing a semiconductor device in accordance with any one of the first to fourth aspects, the semiconductor layer includes a lower semiconductor layer and an upper semiconductor layer, and the semiconductor layer forming gas includes semiconductor material gas and diluent gas. The step of forming the semiconductor layer includes the steps of: forming the lower semiconductor layer on the predetermined layer by introducing the semiconductor layer forming gas into the reaction chamber for another predetermined period of time and allowing the semiconductor layer forming gas to generate a plasma discharge; and forming the upper semiconductor layer so as to cover the lower semiconductor layer by allowing the semiconductor layer forming gas, with an introduction amount ratio changed by modifying an introduction amount ratio of the semiconductor material gas and the diluent gas in the semiconductor layer forming gas after forming the lower semiconductor layer, to generate a plasma discharge. In the step of forming the upper semiconductor layer, a composition set value of gas supplied to the reaction chamber is shifted from a composition of the semiconductor layer forming gas for forming the lower semiconductor layer to a composition of the semiconductor layer forming gas for forming the upper semiconductor layer in a state where a pressure in the reaction chamber is not reduced to ultimate vacuum even after a plasma discharge processing for forming the lower semiconductor layer is terminated.

According to a method for manufacturing a semiconductor device in accordance with an eighth aspect of the present invention, in the method for manufacturing a semiconductor device in accordance with any one of the first to seventh aspects, an introduction amount of the semiconductor layer forming gas into the reaction chamber is reduced to a predetermined flow rate after forming the semiconductor layer.

According to a method for manufacturing a semiconductor device in accordance with a ninth aspect of the present invention, the method for manufacturing a semiconductor device in accordance with any one of the first to eighth aspects of the present invention further includes the step of forming a second conductivity type layer of a second conductivity type on another predetermined layer by supplying another impurity gas onto said another predetermined layer.

According to a method for manufacturing a semiconductor device in accordance with a tenth aspect of the present invention, in the method for manufacturing a semiconductor device in accordance with the ninth aspect of the present invention, the another impurity gas is introduced into the reaction chamber, and the second conductivity type layer is formed in the reaction chamber.

According to a method for manufacturing a semiconductor device in accordance with an eleventh aspect of the present invention, in the method for manufacturing a semiconductor device in accordance with any one of the first to tenth aspects of the present invention, the semiconductor device is a photoelectric conversion device.

According to a method for manufacturing a semiconductor device in accordance with a twelfth of the present invention, in the method for manufacturing a semiconductor device in accordance with any one of the first to eighth aspects of the present invention, the semiconductor device is a switching semiconductor device having a thin-film transistor.

The definition of the term “semiconductor layer” of the present invention will be described in the following. The “semiconductor layer” of the present invention includes an intrinsic semiconductor layer (so-called i-type layer) and a substantially intrinsic semiconductor layer (refer to a first embodiment which will be described later) in a photoelectric conversion device. The intrinsic semiconductor layer mentioned herein is a completely undoped intrinsic semiconductor layer. The substantially intrinsic semiconductor layer described herein is a weak p-type semiconductor layer or a weak n-type semiconductor layer containing a small amount of impurities. Both semiconductor layer and conductivity type layer include an amorphous silicon-based layer and a microcrystal silicon-based layer. The amorphous silicon-based layer mentioned herein includes, for example, a-Si:H, a-SiC:H, a-SiGe:H, a-SiN:H, and the like. The microcrystal silicon-based layer includes, for example, μc-Si:H, pc-SiGe:H, and the like.

The “semiconductor layer” of the present invention includes an amorphous silicon-based layer (refer to a second embodiment which will be described later) and a substantially amorphous silicon-based layer in an inversely-staggered transistor. The amorphous silicon-based layer described herein is a completely undoped amorphous silicon-based layer. The substantially amorphous silicon-based layer described herein is a weak p-type amorphous silicon-based layer or a weak n-type amorphous silicon-based layer containing a small amount of impurities.

The “semiconductor layer” of the present invention does not include an amorphous n-type silicon layer (so-called n⁺ a-Si layer) or an amorphous p-type silicon layer (so-called p⁺ a-Si layer) of an amorphous silicon layer sufficiently doped with n-type impurities or p-type impurities.

### Advantageous Effects of Invention

According to the present invention, a method for manufacturing a semiconductor device by using a plasma CVD method to deposit a conductivity type layer so as to cover a semiconductor layer and allow productivity exhibited after formation of a semiconductor layer and until formation of a conductivity type layer to be improved can be achieved.

### BRIEF DESCRIPTION OF DRAWINGS

FIG. 1 is a cross sectional view of a photoelectric conversion device manufactured by a method for manufacturing a photoelectric conversion device in accordance with a first embodiment.

FIG. 2 schematically represents a plasma CVD device used in the method for manufacturing a photoelectric conversion device in accordance with the first embodiment.

FIG. 3 represents each steps of the method for manufacturing a photoelectric conversion device in accordance with the first embodiment.

FIG. 4 is a timing chart representing operation states of each element in some steps (step S4-step S7) of the method for manufacturing a photoelectric conversion device in accordance with the first embodiment.

FIG. 5 is a cross sectional view of an inversely-staggered thin film transistor manufactured by a method for manufacturing an inversely-staggered thin film transistor in accordance with a second embodiment.

FIG. 6 represent each step of the method for manufacturing an inversely-staggered thin film transistor in accordance with the second embodiment.

### DESCRIPTION OF EMBODIMENTS

Each embodiment in accordance with the present invention will be described hereinafter with the reference to the drawings. In each of the following embodiments, when the number and amount are mentioned, the scope of the present invention is not necessarily limited to the cited number and amount, unless particularly noted otherwise. In each of the embodiments described hereinafter, the identical parts and the corresponding parts have the same reference characters allotted, and description of overlapping parts will not be repeated.

### First Embodiment

The present embodiment will be described based on a method for manufacturing a photoelectric conversion device having a pin junction as an example of a method for manufacturing a semiconductor device. According to the method for manufacturing a photoelectric conversion device in accordance with the present embodiment, a plasma CVD method is used to deposit a conductivity type layer (n-type layer) so as to cover a semiconductor layer (i-type layer). The present invention may be applied to a method for manufacturing an inversely-staggered thin film transistor as another example of a method for manufacturing a semiconductor device. The method for manufacturing an inversely-staggered thin film transistor will be described in detail in a second embodiment described later.

(Photoelectric Conversion Device 100)

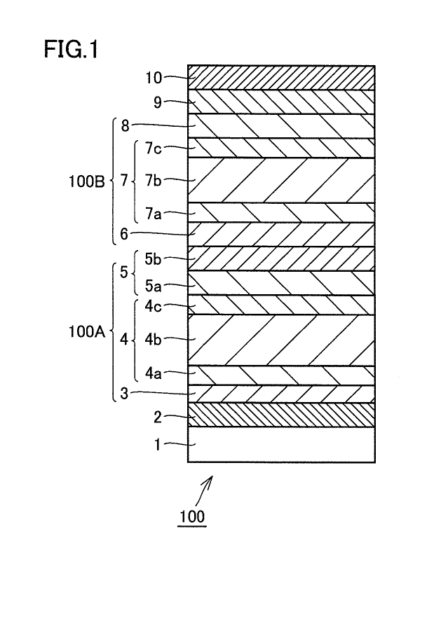

A photoelectric conversion device 100 will be described with reference to FIG. 1. Photoelectric conversion device 100 is manufactured by using a method for manufacturing a photoelectric conversion device in accordance with the present embodiment. Photoelectric conversion device 100 includes a first photoelectric conversion layer 100A having one pin junction, and a second photoelectric conversion layer 100B having another pin junction.

Photoelectric conversion device 100 is configured by sequentially laminating a transparent substrate 1, a transparent conductive film 2, a p-type layer 3, an i-type layer 4, an n-type layer 5, a p-type layer 6, an i-type layer 7, an n-type layer 8, a backside transparent conductive film 9, and a backside metal electrode 10. In photoelectric conversion device 100, a light beam is incident from the side of transparent substrate 1. In photoelectric conversion device 100, the one pin junction (first photoelectric conversion layer 100A) is formed by p-type layer 3, i-type layer 4, and n-type layer 5. In photoelectric conversion device 100, the another pin junction (second photoelectric conversion layer 100B) is formed by p-type layer 6, i-type layer 7, and n-type layer 8.

Transparent substrate 1 and transparent conductive film 2 have translucency. Transparent substrate 1 of a glass substrate, a resin substrate made of polyimide, or the like, having thermal resistance and translucency during the plasma CVD forming process can be employed. Transparent conductive film 2 is made of, for example, SnO₂:F (FTO) or ZnO:Al.

Both p-type layer 3 and p-type layer 6 are doped with p-type impurity atoms such as boron, aluminum, or the like. P-type layer 3 is made of, for example, a-Si:C:B:H. P-type layer 6 is, for example, μc-Si:B:H.

Both i-type layer 4 and i-type layer 7 may be completely undoped intrinsic semiconductor layers or may be substantially intrinsic semiconductor layers such as a weak p-type semiconductor layer or a weak n-type semiconductor layer containing a small amount of impurities.

I-type layer 4 in accordance with the present embodiment is configured by sequentially laminating a p-side buffer layer 4a, a bulk layer 4b, and an n-side buffer layer 4c. Bulk layer 4b is, for example, a-Si:H (hydrogenated amorphous silicon layer) or a-SiGe:H (hydrogenated amorphous silicon germanium layer).

I-type layer 7 in accordance with the present embodiment is configured by sequentially laminating a p-side buffer layer 7a, a bulk layer 7b, and an n-side buffer layer 7c. Bulk layer 7b is, for example, (hydrogenated microcrystal silicon layer) or μc-SiGe:H (hydrogenated microcrystal silicon germanium layer). P-side buffer layers 4a, 7a and n-side buffer layers 4c, 7c may be formed as needed.

N-type layer 5 and n-type layer 8 are doped with n-type impurity atoms such as phosphorus. N-type layer 5 in accordance with the present embodiment is configured by sequentially laminating a substrate-side n-type layer 5a and a backside n-type layer 5b. Substrate-side n-type layer 5a is, for example, a-Si:P:H. Backside n-type layer 5b is, for example, μc-Si:P:H. N-type layer 8 may be configured similarly to n-type layer 5.

(Plasma CVD Device 200)

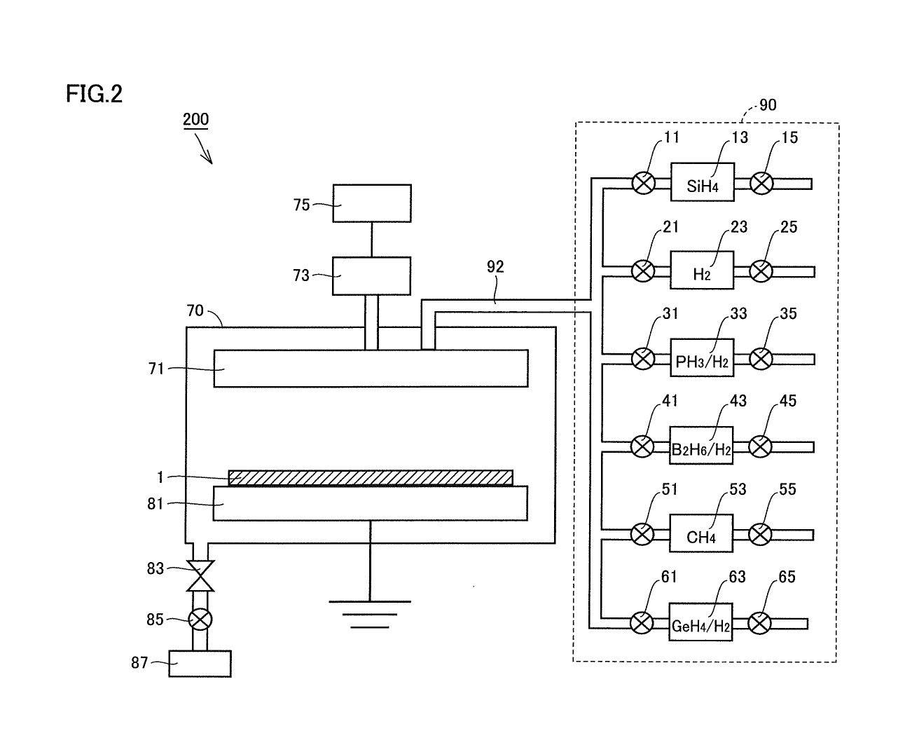

A plasma CVD device 200 used in a method for manufacturing a photoelectric conversion device in accordance with the present embodiment will be described with reference to FIG. 2. Plasma CVD device 200 includes a reaction chamber 70, a cathode electrode 71, a matching box 73, a high frequency power supply 75, an anode electrode 81, a pressure adjusting valve 83, an exhaust valve 85, a vacuum pump 87, a gas introduction system 90, and a gas introduction section 92.

Reaction chamber 70 is configured by a sealable housing. Transparent substrate 1 brought into reaction chamber 70 can be formed to have a p-type layer, an i-type layer, and an n-type layer in reaction chamber 70. Cathode electrode 71 and anode electrode 81 are provided in reaction chamber 70 and have a parallel-plate electrode structure. An electrode distance between cathode electrode 71 and anode electrode 81 is set in accordance with a desired process condition and may be, for example, 1 mm to 40 mm.

Matching box 73 connected to cathode electrode 71 and high frequency power supply 75 connected to matching box 73 are provided outside of reaction chamber 70. High frequency power supply 75 supplies power to cathode electrode 71 through matching box 73. Matching box 73 matches impedance of high frequency power supply 75 with respect to cathode electrode 71 and anode electrode 81.

High frequency power supply 75 outputs CW (continuous waveform) alternate current output, or alternate current power (RF power) having pulse modulation (ON—OFF control) applied. High frequency power supply 75 may switch and output these alternate current powers. A frequency of alternate current power output from high frequency power supply 75 is, for example, 13.56 MHz. A frequency of alternate current output from high frequency power supply 75 may be from several kHz to VHF-band or microwave-band.

Anode electrode 81 is electrically grounded. Transparent substrate 1 is placed on anode electrode 81. Transparent substrate 1 may be placed on anode electrode 81 in a state where transparent conductive film 2 (not shown in FIG. 2) is formed. Transparent substrate 1 may be placed on anode electrode 81 in a state where transparent conductive film 2 and p-type layer 3 are formed. Transparent substrate 1 may be placed on cathode electrode 71. Transparent substrate 1 is preferably provided on anode electrode 81 to reduce deterioration of film quality due to ion damage caused by plasma.

Gas introduction system 90 arranged outside of reaction chamber 70 includes: a valve 11, an SiH₄ gas flow rate control device 13, and a valve 15 connected sequentially; a valve 21, an H₂ gas flow rate control device 23, and a valve 25 connected sequentially; a valve 31, a PH₃/H₂ gas flow rate control device 33, and a valve 35 connected sequentially; a valve 41, a B₂H₆/H₂ gas flow rate control device 43, and a valve 45 connected sequentially; a valve 51, a CH₄ gas flow rate control device 53, and a valve 55 connected sequentially; and a valve 61, a GeH₄/H₂ gas flow rate control device 63, and a valve 65 connected sequentially. Valves 11, 21, 31, 41, 51 and 61 are connected to gas introduction section 92 in communication with inside of reaction chamber 70.

Valve 15 is connected to a tank (not illustrated) for supplying silane gas (SiH₄ gas). Opening valve 11 and valve 15 allows silane gas (SiH₄ gas) to be introduced from this tank into reaction chamber 70 through SiH₄ gas flow rate control device 13 and gas introduction section 92.

Valve 25 is connected to a tank (not illustrated) for supplying hydrogen gas (H₂ gas). Opening valve 21 and valve 25 allows hydrogen gas (H₂ gas) to be introduced from this tank into reaction chamber 70 through H₂ gas flow rate control device 23 and gas introduction section 92.

Valve 35 is connected to a tank (not illustrated) for supplying phosphine gas (PH₃/H₂ gas). Opening valve 31 and valve 35 allows phosphine gas (PH₃/H₂ gas) to be introduced from this tank into reaction chamber 70 through PH₃/H₂ gas flow rate control device 33 and gas introduction section 92.

Valve 45 is connected to a tank (not illustrated) for supplying diborane gas (B₂H₆/H₂ gas). Opening valve 41 and valve 45 allows diborane gas (B₂H₆/H₂ gas) to be introduced from this tank into reaction chamber 70 through B₂H₆/H₂ gas flow rate control device 43 and gas introduction section 92.

Valve 55 is connected to a tank (not illustrated) for supplying methane gas (CH₄ gas). Opening valve 51 and valve 55 allows methane gas (CH₄ gas) to be introduced from this tank into reaction chamber 70 through CH₄ gas flow rate control device 52 and gas introduction section 92.

Valve 65 is connected to a tank (not illustrated) for supplying GeH₄/H₂ gas. Opening valve 61 and valve 65 allows GeH₄/H₂ gas to be introduced from this tank into reaction chamber 70 through GeH₄/H₂ gas flow rate control device 63 and gas introduction section 92.

Pressure adjusting valve 83, exhaust valve 85 and vacuum pump 87 connected sequentially are provided outside of reaction chamber 70, and pressure adjusting valve 83 is connected to reaction chamber 70. Vacuum pump 87 may be of a type capable of highly evacuating reaction chamber 70 to have a gas pressure of less than or equal to a pressure of 10⁻⁶ Torr (≈10⁻⁴ Pa). Vacuum pump 87 may be of a type having discharging ability to achieve ultimate vacuum of 10⁻³ Torr (≈0.1 Pa) in reaction chamber 70, in view of device simplification, cost reduction, and throughput improvement.

As the substrate size of a semiconductor device becomes larger, a capacity of reaction chamber 70 becomes larger. When reaction chamber 70 having a large capacity is highly evacuated, high-performance vacuum pump 87 can be used. Simple vacuum pump 87 for a low vacuum can also be used. In this case, device simplification and cost reduction can be achieved. Simple vacuum pump 87 for a low vacuum may be, for example, a dry pump, a rotary pump, a mechanical booster pump, and the like. These pumps can be used individually or in combination of two or more pumps.

A volume of reaction chamber 70 of the plasma CVD device used in the present embodiment is, for example, about 1 m³. Vacuum pump 87 of a type having a mechanical booster pump and a rotary pump connected in series can be used. Alternatively, a dry pump can be used.

Pressure adjusting valve 83, exhaust valve 85 and vacuum pump 87 set the gas pressure in reaction chamber 70 to a predetermined value (details will be described later). In a state where a pressure in reaction chamber 70 is set to a predetermined value, high frequency power supply 75 and matching box 73 supply a predetermined amount of power to cathode electrode 71. Plasma is generated between cathode electrode 71 and anode electrode 81, and gas supplied to reaction chamber 70 is dissolved. Consequently, a p-type layer, an i-type layer, an n-type layer, or the like is formed on transparent substrate 1 (details will be described next).

(Method for Manufacturing Photoelectric Conversion Device 100)

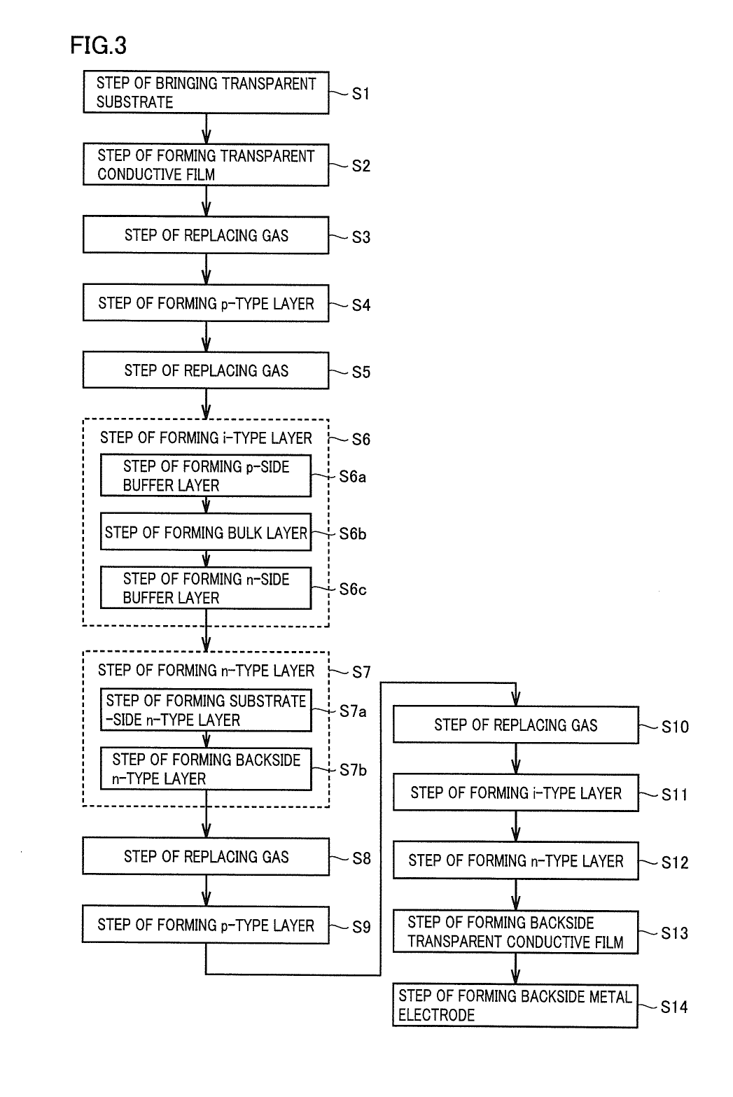

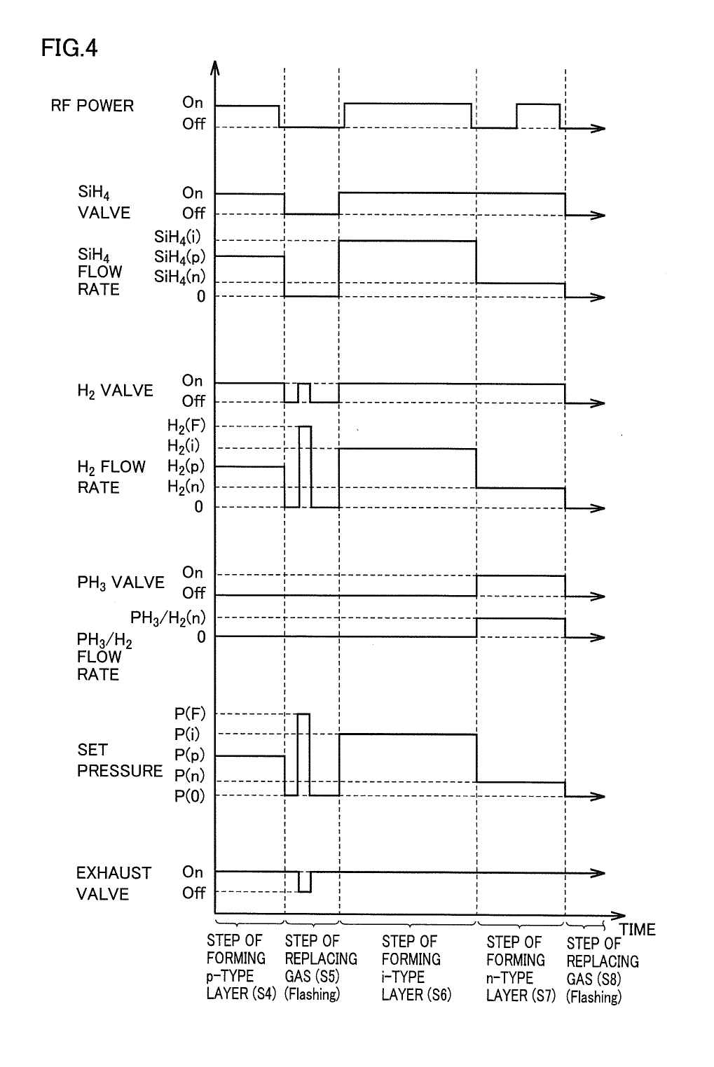

With reference to FIG. 3, a method for manufacturing photoelectric conversion device 100 (steps S1-S14) will be described in order as follows. Steps S4-S7 will be described also with reference to the timing chart shown in FIG. 4.

(Step S1: Step of Bringing Transparent Substrate, and Step S2: Step of Forming Transparent Conductive Film)

Firstly, transparent substrate 1 is brought into reaction chamber 70 in plasma CVD device 200 (step S1). In reaction chamber 70, transparent conductive film 2 is formed on transparent substrate 1 (step S2). In another device (not illustrated), a method such as CVD, sputtering, vapor deposition, or the like may be used to form transparent conductive film 2 on transparent substrate 1. Thereafter, transparent substrate 1 may be brought into reaction chamber 70 in a state where transparent conductive film 2 is formed.

(Step S3: Step of Replacing Gas)

In reaction chamber 70, there are remaining impurities, such as impurities introduced in step S2 and impurities mixed in from outside at the time of bringing transparent substrate 1 in step S1. When the impurities are incorporated into p-type layer 3 formed in step S4 described later, the quality of p-type layer 3 is deteriorated. To reduce concentration of impurities in reaction chamber 70, gas replacement using replacement gas is applied to reaction chamber 70 (step S3).

Specifically, hydrogen gas (H₂ gas), for example, is introduced into reaction chamber 70 as the replacement gas. After the pressure in reaction chamber 70 reaches a predetermined pressure (for example, from 100 Pa to 1000 Pa), introduction of hydrogen gas is stopped. Introduction of hydrogen gas is performed for about 1 to 5 seconds. After a predetermined period of time has passed, pressure adjusting valve 83 and exhaust valve 85 are opened, and vacuum pump 87 discharges hydrogen gas from reaction chamber 70 until the pressure reaches a predetermined pressure (for example, from 1 Pa to 10 Pa). Discharge by vacuum pump 87 is performed for about 30-60 seconds.

Introduction of hydrogen gas and discharge by vacuum pump 87 can be performed repeatedly for several times. In this case, the pressure in reaction chamber 70 after introduction of hydrogen gas and the pressure in reaction chamber 70 after discharge of hydrogen gas are set in advance. When hydrogen gas is introduced, discharge from reaction chamber 70 is stopped. When the pressure in reaction chamber 70 becomes greater than or equal to the pressure set in advance, introduction of hydrogen gas is stopped. When hydrogen gas is discharged, introduction of hydrogen gas is stopped. When the pressure in a reaction chamber 70 becomes less than or equal to the pressure set in advance, discharge of hydrogen gas is stopped.

The replacement gas is not limited to hydrogen gas, and silane gas (SiH₄ gas) or the like used for forming i-type layer 4 (step S6) described later may be used. The gas used for forming i-type layer 4 (semiconductor layer forming gas) may be used for forming any of p-type layer 3, i-type layer 4, and n-type layer 5. Using the gas for forming i-type layer 4 as the replacement gas prevents the event of causing the gas to mix impurities into p-type layer 3 and n-type layer 5.

Inert gas such as argon gas (Ar gas), neon gas (Ne gas), xenon gas (Xe gas), or the like may be used as the replacement gas. Gas having a great atomic weight is likely to remain in reaction chamber 70 when gas is discharged from reaction chamber 70. Therefore, such gas may be favorably used as the replacement gas. The replacement gas may be mixed gas including one or more type of gas used for forming i-type layer 4 (step S5) (semiconductor layer forming gas) and one or more type of inert gas.

(Step S4: Step of Forming p-Type Layer)

After gas replacement of reaction chamber 70 is performed in step S3, p-type layer 3 (second conductive type layer) is formed so as to cover transparent conductive film 2 (step S4). Herein, FIG. 4 schematically shows a timing chart of each element in steps S4-S7 (details of step S8 is not illustrated).

FIG. 4 shows states over time as to On/Off of alternate current power (RF power), On/Off of SiH₄ valve (corresponding to valves 11, 15 in FIG. 2), a flow rate of silane gas (SiH₄ gas) into reaction chamber 70, On/Off of H₂ valve (corresponding to valves 21, 25 in FIG. 2), a flow rate of hydrogen gas (H₂ gas) into reaction chamber 70, On/Off of PH₃ gas valve (corresponding to valves 31, 35 in FIG. 2), a flow rate of PH₃/H₂ gas into reaction chamber 70, and a set pressure P in reaction chamber 70 adjusted by pressure adjusting valve 83, exhaust valve 85, and vacuum pump 87 for mixture of these gases, and On/Off of the exhaust valve 85. As to On/Off of alternate current power (RF power) shown in FIG. 4, the state of discharging is indicated as On in either states of sequential discharging and pulse discharging, and the state of not discharging is indicated as Off.

Referring to FIGS. 2 and 4, p-type layer forming impurity gas is introduced into reaction chamber 70 to form p-type layer 3. In this stage, exhaust valve 85 is open (exhaust valve On), and reaction chamber 70 is adjusted to have a predetermined pressure by pressure adjusting valve 83. When p-type layer forming impurity gas is introduced, PH₃ valve is closed (PH₃ valve Off), and phosphine gas (PH₃ gas) is not introduced into reaction chamber 70.

P-type layer forming impurity gas includes silane gas (SiH₄ gas), hydrogen gas (H₂ gas), and a diborane gas (B₂H₆ gas). Silane gas (SiH₄ gas) is introduced with a predetermined flow rate (SiH₄ (p) in FIG. 4) by opening the SiH₄ valve (SiH₄ valve On). Hydrogen gas (H₂ gas) is also introduced with a predetermined flow rate (H₂ (p) in FIG. 4) by opening the H₂ valve (H₂ valve On). Although not illustrated in FIG. 4, diborane gas (B₂H₆ gas) is also introduced with a predetermined flow rate.

The flow rate of hydrogen gas (H₂ gas) is, for example, several times to tens of times to that of silane gas (SiH₄ gas). P-type layer forming impurity gas may include methane gas (CH₄ gas) (not illustrated in FIG. 4) containing carbon atoms to reduce a photo-absorption amount.

As described above, in the state where p-type layer forming impurity gas is introduced, the pressure in reaction chamber 70 is maintained substantially constant by pressure adjusting valve 83 (set pressure (p) in FIG. 4). High frequency power supply 75 and matching box 73 supply alternate current power to cathode electrode 71 (RF power On). Plasma is generated between cathode electrode 71 and anode electrode 81. P-type layer forming impurity gas is dissolved (disassociated) and diffused by a plasma discharge to form p-type layer 3 so as to cover transparent conductive film 2. After p-type layer 3 is formed, supply of alternate current power by high frequency power supply 75 is stopped (RF power Off).

(Step S5: Step of Replacing Gas)

Next, the step of replacing gas is conducted in a manner similar to step S3 described above. The step of replacing gas suppresses impurities (particularly, impurities determining a conductivity type of p-type layer 3) from being mixed into i-type layer 4 formed in step S6.

Specifically, introduction of silane gas (SiH₄ gas) into reaction chamber 70 is stopped by closing SiH₄ valve (SiH₄ valve Off). Introduction of hydrogen gas (H₂ gas) into reaction chamber 70 is stopped by closing H₂ valve (H₂ valve Off). Similarly, introduction of diborane gas (B₂H₆ gas) into reaction chamber 70 is also stopped. After introduction of each gas is stopped, reaction chamber 70 is evacuated by vacuum pump 87 until the pressure in reaction chamber 70 reaches a predetermined pressure (set pressure P (0) in FIG. 4; for example, from 1 Pa to 10 Pa) in the opened state where exhaust valve 85 is opened (exhaust valve On).

Next, exhaust valve 85 is closed (exhaust valve Off), and hydrogen gas (H₂ gas) is introduced (H₂ valve On). Hydrogen gas (H2 gas) is introduced until the pressure in reaction chamber 70 reaches a predetermined pressure (set pressure P (F) in FIG. 4). Thereafter, introduction of hydrogen gas (H₂ gas) is stopped (H₂ valve Off), and exhaust valve 85 is opened again (exhaust valve On). Vacuum pump 87 evacuates reaction chamber 70 until the pressure in reaction chamber 70 reaches a predetermined pressure (set pressure P (0) in FIG. 4). The introduction of hydrogen gas and discharge by vacuum pump 87 may be repeated several times. With the procedures described above, the step of replacing gas is completed.

(Step S6: Step of Forming i-Type Layer)

Next, i-type layer 4 is formed (step S6). I-type layer 4 may be a completely undoped intrinsic semiconductor layer or may be a substantially intrinsic semiconductor layer such as a weak p-type semiconductor layer or a weak n-type semiconductor layer containing a small amount of impurities.

In step S6 of the present embodiment, p-side buffer layer 4a of i-type layer 4 is firstly formed (step S6a). In the state where exhaust valve 85 is opened (exhaust valve On), silane gas (SiH₄ gas) and hydrogen gas (H₂ gas) are introduced into reaction chamber 70 as semiconductor layer forming gas (SiH₄ valve On, H₂ valve On). The flow rate of hydrogen gas (H₂ gas) (H₂ (i) in FIG. 4) is, for example, about 1 time to about 50 times the flow rate of silane gas (SiH₄ gas) (SiH₄ (i) in FIG. 4). Semiconductor layer forming gas may include disilane gas (Si₂H₆ gas), germanium gas (GeHₜ gas), or methane gas (CH₄ gas) containing carbon atoms for reducing photo-absorption amount. The semiconductor layer forming gas may include argon gas (Ar gas), or helium gas (He gas).

In the state where the semiconductor layer forming gas is introduced, the pressure in reaction chamber 70 is maintained substantially constant set pressure P (i) in FIG. 4 by pressure adjusting valve 83. (The set pressure for forming p-side buffer layer 4a may be different from the set pressure for forming bulk layer 4b.) High frequency power supply 75 and matching box 73 supply alternate current power to cathode electrode 71 (RF power On). Plasma is generated between cathode electrode 71 and anode electrode 81. The semiconductor layer forming gas is dissolved (disassociated) and diffused, and p-side buffer layer 4a is formed so as to cover p-type layer 3. Formation of p-side buffer layer 4a lowers the concentration of boron atoms in an atmosphere of reaction chamber 70, so that mixing of boron atoms into bulk layer 4b formed in step S6b described next is reduced.

Then, a bulk layer 4b of i-type layer 4 is formed on p-side buffer layer 4a (step S6b). In the state of step S6a, adjustment of SiH₄ gas flow rate control device 13 and H₂ gas flow rate control device 23 changes the flow rate (introduction amount ratio) of hydrogen gas (H₂ gas) to be, for example, from about 35 times to about 70 times to that of silane gas (SiH₄ gas) (details are not described in FIG. 4).

The change in the flow rate (introduction amount ratio) of hydrogen gas (H₂ gas) relative to silane gas (SiH₄ gas) is preferably achieved by changing the introduction amount of each of silane gas (SiH₄ gas) and hydrogen gas (H₂ gas) in the state where the introduction amount of semiconductor layer forming gas as a whole is maintained. Further, as to the change in the flow rate of hydrogen gas (H₂ gas) relative to silane gas (SiH₄ gas), the introduction amount of the semiconductor layer forming gas as a whole may be increased or reduced as a result of the change in introduction amount of each of silane gas (SiH₄ gas) and hydrogen gas (H₂ gas).

Also in this stage, the pressure in reaction chamber 70 is maintained substantially constant (set pressure P (i) in FIG. 4) by pressure adjusting valve 83 in the state where exhaust valve 85 is opened. The semiconductor layer forming gas having a changed flow rate ratio (mixture ratio) is dissolved (disassociated) and diffused by a plasma discharge, and bulk layer 4b is formed so as to cover p-side buffer layer 4a.

Next, an n-side buffer layer 4c of i-type layers 4 is formed (step S6c). In the state of step S6b described above, adjustment of SiH₄ gas flow rate control device 13 and H₂ gas flow rate control device 23 changes the flow rate of hydrogen gas (H₂ gas) to be, for example, about 1 time to 50 times to that of silane gas (SiH₄ gas) (details are not described in FIG. 4). Also in this stage, in the state where exhaust valve 85 is opened, the pressure in reaction chamber is maintained substantially constant (set pressure P (i) in FIG. 4) by pressure adjusting valve 83 (The set pressure for forming n-side buffer layer 4c may be different from the set pressure for forming bulk layer 4b).

The semiconductor layer forming gas having a changed flow rate ratio (mixture ratio) is dissolved (disassociated) and diffused by a plasma discharge to form n-side buffer layer 4c so as to cover bulk layer 4b. In this manner, p-side buffer layer 4a, bulk layer 4b, and n-side buffer layer 4c are deposited to form i-type layer 4. P-side buffer layer 4a and n-side buffer layer 4c may be formed as needed. After i-type layer 4 (n-side buffer layer 4c) having a predetermined thickness is formed, supply of alternate current power by high frequency power supply 75 is stopped (RF power Off).

(Step S7: Step of Forming n-Type Layer)

Next, a substrate-side n-type layer 5a (lower first conductivity type layer) of n-type layer 5 (first conductivity type layer) is firstly formed (step S7a). N-type layer 5 described herein corresponds to an n-type layer in a super-straight type thin film photoelectric conversion device such as photoelectric conversion device 100. N-type layer 5 described herein corresponds to a p-type layer in the so-called sub-straight type thin film photoelectric conversion device. N-type layer 5 described herein corresponds to an n-type layer (n⁺ a-Si layer) in the so-called inversely-staggered thin film transistor (details about an inversely-staggered thin film transistor will be described in the second embodiment).

In step S7a, silane gas (SiH₄ gas) and hydrogen gas (H₂ gas) are supplied to reaction chamber 70 as semiconductor layer forming gas, and n-type impurity gas is additionally introduced into reaction chamber 70. This n-type impurity gas includes phosphine gas (PH₃ gas). The phosphine gas (PH₃ gas) is introduced into reaction chamber 70 by opening the PH₃/H₂ valve (PH₃/H₂ valve On). When the n-type impurity gas is introduced, the condition for forming i-type layer 4 and the condition for forming n-type layer 5 (substrate-side n-type layer 5a) may be different in the introduction conditions (flow rate, mixture ratio, and the like) of silane gas (SiH₄ gas) and hydrogen gas (H₂ gas).

Herein, when n-type layer 5 (substrate-side n-type layer 5a) is formed, n-type impurity gas is preferably introduced into reaction chamber 70 in the state where introduction of semiconductor layer forming gas into reaction chamber 70 is not stopped even after a plasma discharge processing for forming i-type layer 4 (n-side buffer layer 4c) is terminated. After the plasma discharge processing for forming i-type layer 4 (n-side buffer layer 4c) is terminated, n-type impurity gas may be introduced into reaction chamber 70 while introduction of semiconductor layer forming gas into reaction chamber 70 is performed intermittently (with introduction/stopping at least once). The semiconductor layer forming gas and n-type impurity gas are mixed to form n-type layer forming gas. In the state where the pressure in reaction chamber 70 is not reduced to ultimate vacuum even after a plasma discharge processing for forming i-type layer 4 (n-side buffer layer 4c) is terminated, a composition set value (atmosphere) in reaction chamber 70 is shifted from a composition of semiconductor layer forming gas (the state where the semiconductor layer forming gas is dominant) to a composition of n-type layer forming gas (appropriate mixed gas including n-type impurity gas and semiconductor layer forming gas) (the state where the n-type layer forming gas is dominant).

The state (atmosphere) where the semiconductor layer forming gas is dominant as mentioned here represents the atmosphere defined by a supply composition (set value) of semiconductor layer forming gas. The state (atmosphere) where n-type layer forming gas is dominant as described herein represents the atmosphere defined by a supply composition (set value) of n-type layer forming gas.

The ultimate vacuum as mentioned herein represents the state where substantially no (zero) flow rate of gas component flowing from reaction chamber 70 to outside of reaction chamber 70 by vacuum pump 87 is present. Further, the state where the pressure in reaction chamber 70 is not reduced to ultimate vacuum as described herein represents the state where the pressure in reaction chamber 70 is higher than the ultimate vacuum. Set pressure P (0) in FIG. 4 indicates the state where pressure adjusting valve 83 is fully opened, and the pressure in reaction chamber 70 is not necessarily at the ultimate vacuum.

In the state where semiconductor layer forming gas and n-type impurity gas are introduced into reaction chamber 70, the pressure in reaction chamber 70 is maintained substantially constant (set pressure P (n) in FIG. 4) by pressure adjusting valve 83. When formation of n-type layer 5a is started, the flow rate of hydrogen gas (H₂ gas) (H₂ (n) in FIG. 4) is set to be about 5 times to about 300 times the flow rate of silane gas (SiH₄ gas) (SiH₄ (n) in FIG. 4).

In order to shift the state where the semiconductor layer forming gas is dominant to the state where the n-type layer forming gas is dominant in a shorter period of time, the introduction amount of silane gas (SiH₄ gas) and hydrogen gas (H₂ gas) into reaction chamber 70 may be set smaller as shown in FIG. 4. When the introduction amount of semiconductor layer forming gas into reaction chamber 70 is set smaller, the state (atmosphere) where semiconductor layer forming gas is dominant represents the atmosphere defined by a supply composition (set value) of semiconductor layer forming gas immediately before completing formation of i-type layer 4. Until the state where the semiconductor layer forming gas is dominant is shifted to the state where the n-type layer forming gas is dominant, supply of alternate current power may be stopped as shown in FIG. 4 (RF power Off).

After the state where the semiconductor layer forming gas is dominant is shifted to the state where n-type layer forming gas is dominant, high frequency power supply 75 and matching box 73 supply alternate current power to cathode electrode 71 (RF power On). Plasma is generated between cathode electrode 71 and anode electrode 81. The n-type layer forming gas is dissolved (disassociated) and diffused by a plasma discharge to form substrate-side n-type layer 5a so as to cover i-type layer 4 (n-side buffer layer 4c).

Next, a backside n-type layer 5b (upper first conductivity type layer) of n-type layer 5 is formed on substrate-side n-type layer 5a (step S7b). In the state of step S7a, adjustment of SiH₄ gas flow rate control device 13 and H₂ gas flow rate control device 23 changes the flow rate of hydrogen gas (H₂ gas) from about 30 times to 300 times to that of silane gas (SiH₄ gas) (details are not described in FIG. 4). Also in this stage, the pressure in the reaction chamber 70 is maintained substantially constant by pressure adjusting valve 83 (set pressure P (n) in FIG. 4) in the state where exhaust valve 85 is opened.

The adjustment described above also changes the introduction amount ratio (mixture ratio) of phosphine gas (PH₃ gas) relative to the introduction amount of semiconductor layer forming gas. N-type layer forming gas including phosphine gas (PH₃ gas) and semiconductor layer forming gas having a changed introduction amount ratio is dissolved (disassociated) and diffused by a plasma discharge to form backside n-type layer 5b so as to cover substrate-side n-type layer 5a. After n-type layer 5 (backside n-type layer 5b) having a predetermined thickness is formed, supply of alternate current power by high frequency power supply 75 is stopped (RF power Off).

The laminated structure of substrate-side n-type layer 5a and backside n-type layer 5b in n-type layer 5 may be employed as needed. A plurality of n-type layers having different impurity concentrations may be formed as n-type layer 5 by adjustment of SiH₄ gas flow rate control device 13 and/or H₂ gas flow rate control device 23 and/or PH₃/H₂ gas flow rate control device 33. N-type layer 5 may be formed by laminating an n-type amorphous layer and an n-type microcrystal layer, by only an n-type amorphous layer, or by only an n-type microcrystal layer.

When n-type layer 5 is formed by laminating a plurality of n-type layers having different impurity concentrations, or when n-type layer 5 is formed by laminating an n-type amorphous layer and an n-type microcrystal layer, the state (atmosphere) where n-type layer forming gas is dominant represents the atmosphere defined by an n-type layer forming gas supply composition (set value) in the stage of starting formation of a layer in contact with i-type layer 4 (n-side buffer layer 4c). In the manner described above, first photoelectric conversion layer 100A having a pin junction is formed on transparent conductive film 2.

(Step S8: Step of Replacing Gas)

Next, in a manner similar to step S3 described above, step of replacing gas is conducted. The step of replacing gas suppresses impurities (particularly, impurities determining a conductivity type of n-type layer 5) from being mixed into p-type layer 6 formed in step S9 described next.

(Step S9: Step of Forming p-Type Layer)

Next, in a manner similar to p-type layer 3 in first photoelectric conversion layer 100A, p-type layer 6 is formed so as to cover backside n-type layer 5b.

(Step S10: Step of Replacing Gas)

Next, in a manner similar to step S5 described above, step of replacing gas is conducted. The step of replacing gas suppresses impurities (particularly, impurities determining a conductivity type of p-type layer 6) from being mixed into i-type layer 7 formed in step S11 described next).

(Step S11: Step of Forming i-Type Layer)

Next, in a manner similar to step S6a, step S6b, and step S6c included in step S6 described above, a p-side buffer layer 7a, a bulk layer 7b, and an n-side buffer layer 7c are formed respectively.

(Step S12: Step of Forming n-Type Layer)

Next, in a manner similar to step S7 described above, n-type layer 8 is formed. N-type layer 8 may have a laminated structure including an n-type microcrystal layer and an n-type amorphous layer. Alternatively, n-type layer 8 may included only either one of n-type microcrystal layer and n-type amorphous layer. Further, n-type layer 8 can be formed by laminating a plurality of n-type layers having different impurity concentrations. Alternatively, n-type layer 8 can be formed from a single layer having a predetermined impurity concentration.

In the state where silane gas (SiH₄ gas) and hydrogen gas (H₂ gas) are supplied as semiconductor layer forming gas into reaction chamber 70, n-type impurity gas is introduced additionally into reaction chamber 70. The n-type impurity gas includes phosphine gas (PH₃ gas).

Herein, when n-type layer 8 is formed, n-type impurity gas is preferably introduced into reaction chamber 70 in a state where introduction of semiconductor layer forming gas into reaction chamber 70 is not stopped even after a plasma discharge processing for forming i-type layer 7 is terminated. After the plasma discharge processing for forming i-type layer 7 is terminated, n-type impurity gas may be introduced into reaction chamber 70 while introduction of semiconductor layer forming gas into reaction chamber 70 is performed intermittently (with introduction/stopping at least once). Semiconductor layer forming gas and n-type impurity gas are mixed to produce n-type layer forming gas. In the state where the pressure in reaction chamber 70 is not reduced to ultimate vacuum even after the plasma discharge processing for forming i-type layer 7 is terminated, a composition set value (atmosphere) in reaction chamber 70 is shifted from a composition of semiconductor layer forming gas (the state where semiconductor layer forming gas is dominant) to a composition of n-type layer forming gas (the state where n-type layer forming gas is dominant).

After the state where the semiconductor layer forming gas is dominant is shifted to the state where n-type layer forming gas is dominant, high frequency power supply 75 and matching box 73 supply alternate current power to cathode electrode 71 (RF power On). Plasma is generated between cathode electrode 71 and anode electrode 81. N-type layer forming gas is dissolved (disassociated) and diffused by a plasma discharge to form n-type layer 8 so as to cover i-type layer 7 (n-side buffer layer 7c). In the manner described above, second photoelectric conversion layer 100B having a pin junction is formed on first photoelectric conversion layer 100A.

(Step S13: Step of Forming Backside Transparent Conductive Film)

Next, backside transparent conductive film 9 is formed on second photoelectric conversion layer 100B (n-type layer 8). Backside transparent conductive film 9 is formed of SnO₂, ITO, or ZnO by using a method such as CVD, sputtering, or vapor deposition.

(Step S14: Step of Forming Backside Metal Electrode)

Next, backside metal electrode 10 is formed on backside transparent conductive film 9. Backside metal electrode 10 is formed of metal such as silver or aluminum by using a method such as CVD, sputtering, or vapor deposition. In the manner described above, the steps for manufacturing photoelectric conversion device 100 according to the present embodiment is completed.

(Operation and Effect)

According to the method for manufacturing photoelectric conversion device 100 in accordance with the present embodiment, after i-type layer 4 is formed, formation of n-type layer 5 is started without highly evacuating reaction chamber 70. Further, after i-type layer 7 is formed, formation of n-type layer 8 is started without highly evacuating reaction chamber 70. According to the method described above, energy and time for highly evacuating reaction chamber 70 once before forming n-type layer 5 and n-type layer 8 are not required. Therefore, productivity is improved.

As to formation of n-type layer 5 (step S7), bringing transparent substrate 1 into reaction chamber 70 (step S1) is considered to cause impurities such as moisture to be mixed into reaction chamber 70 together with transparent substrate 1. The impurities such as moisture are likely to adhere to locations near an inner wall of reaction chamber 70 and a vacuum system (pressure adjusting valve 83, exhaust valve 85, and vacuum pump 87) at the end of step of forming i-type layer (step S6) after conducting the step of replacing gas (step S3), the step of forming a p-type layer (step S4), and the step of replacing gas (step S5).

In this state, when reaction chamber 70 is highly evacuated so as to have a vacuum degree of less than or equal to 10⁻⁴ Pa (10⁻⁶ Torr) in reaction chamber 70 as shown in Japanese Patent Laying-Open No. 04-266067 (PTD 1) and Japanese Patent Laying-Open No. 2009-004702 (PTD 2) described in the opening sentences, the moisture adhered to reaction chamber 70 and the vacuum system is separated and once float in the gaseous atmosphere of reaction chamber 70. The floating moisture and the like adhere to transparent substrate 1 (i-type layer 4) subject to processing. Moisture and the like adhered to transparent substrate 1 (i-type layer 4) are likely to reside on transparent substrate 1 (i-type layer 4) also by gas replacement.

According to the method for manufacturing photoelectric conversion device 100 in accordance with the present embodiment, semiconductor layer forming gas is present in reaction chamber 70 also in the step of forming n-type layer 5 after forming i-type layer 4. When n-type layer 5 is formed, reaction chamber 70 is not highly evacuated. Therefore, moisture hardly floats and adheres to transparent substrate 1 (i-type layer 4) subject to processing. Even when moisture adhered to reaction chamber 70 and vacuum system float in the gaseous atmosphere of reaction chamber 70, the moisture is considered to collide with the semiconductor layer forming gas present in reaction chamber 70 and be suppressed from reaching transparent substrate 1 (i-type layer 4) subject to processing.

Therefore, according to the method for manufacturing photoelectric conversion device 100 in accordance with the present embodiment, presence of semiconductor layer forming gas in reaction chamber 70 also in the step of forming n-type layer 5 causes impurities such as moisture to be hardly mixed into n-type layer 5. This similarly applies to formation of n-type layer 8.

When i-type layer 4 is formed, the flow rate of hydrogen gas (H₂ gas) relative to silane gas (SiH₄ gas) is changed by adjustment of SiH₄ gas flow rate control device 13 and/or H₂ gas flow rate control device 23 to form p-side buffer layer 4a, bulk layer 4b, and n-side buffer layer 4c. Since the SiH₄ valve and the H₂ valve are not opened or closed, the durable time periods of these valves are long. This similarly applies to formation of i-type layer 7.

Similarly, when n-type layer 5 is formed, the flow rate ratio of silane gas (SiH₄ gas), hydrogen gas (H₂ gas), and PH₃/H₂ gas is changed by adjustment of SiH₄ gas flow rate control device 13 and/or H₂ gas flow rate control device 23 and/or PH₃/H₂ gas flow rate control device 33 to form substrate-side n-type layer 5a and backside n-type layer 5b. Since the SiH₄ valve, H₂ valve, and PH₃/H₂ valve are not opened or closed, the durable time periods of these valves are long.

The method for manufacturing photoelectric conversion device 100 in accordance with the present embodiment corresponds to the so-called single chamber type of depositing each layer on transparent substrate 1 in one reaction chamber 70. As compared to a multi-chamber type or the like having a plurality of reaction chambers, equipment costs and running costs are lower. According to the method for manufacturing photoelectric conversion device 100 in accordance with the present embodiment, a photoelectric conversion device can be obtained in a less expensive manner.

[Another Mode of the First Embodiment]

In the method for manufacturing photoelectric conversion device 100 described above, first photoelectric conversion layer 100A and second photoelectric conversion layer 100B are formed on transparent substrate 1 (transparent conductive film 2). Only first photoelectric conversion layer 100A may be formed on transparent substrate 1 (transparent conductive film 2). First photoelectric conversion layer 100A, second photoelectric conversion layer 100B, and a plurality of another photoelectric conversion layers may be formed on transparent substrate 1 (transparent conductive film 2).

In the method for manufacturing photoelectric conversion device 100 described above, p-type layer 3, i-type layer 4, and n-type layer 5 are successively formed as first photoelectric conversion layer 100A in reaction chamber 70. In a reaction chamber other than reaction chamber 70, p-type layer 3 is formed so as to cover transparent conductive film 2 provided on transparent substrate 1. The step of forming i-type layer (step S6) and the step of forming n-type layer (step S7) may be conducted after transparent substrate 1 is brought into reaction chamber 70. In this case, the step of replacing gas (step S5) described above may also be conducted as needed before conducting the step of forming i-type layer described above (step S6). This similarly applies to the step of replacing gas (step S10), the step of forming i-type layer (step S11), and the step of forming n-type layer (step S12) for second photoelectric conversion layer 100B.

In the method for manufacturing photoelectric conversion device 100 described above, i-type layer 4 is formed from p-side buffer layer 4a, bulk layer 4b, and n-side buffer layer 4c. I-type layer 4 may be formed from p-side buffer layer 4a (lower semiconductor layer) and bulk layer 4b (upper semiconductor layer). I-type layer 4 may be formed from bulk layer 4b (lower semiconductor layer) and n-side buffer layer 4c (upper semiconductor layer). This similarly applies to i-type layer 7.

In the method for manufacturing photoelectric conversion device 100 described above, silane gas (SiH₄ gas) is used as semiconductor material gas, and hydrogen gas (H₂ gas) is used as diluted gas to form i-type layer 4. Disilane gas (Si₂H₆ gas), germanium gas (GeH₄ gas), or methane gas (CH₄ gas) may be used as semiconductor material gas. Argon gas (Ar gas), helium gas (He gas), or nitrogen gas (N₂ gas) may be used as diluted gas.

In the method for manufacturing photoelectric conversion device 100 described above, i-type layer 4 is formed from p-side buffer layer 4a, bulk layer 4b, and n-side buffer layer 4c by adjustment of SiH₄ gas flow rate control device 13 and H₂ gas flow rate control device 23. As to i-type layer 4, p-side buffer layer 4a may be formed by introduction of semiconductor layer forming gas (first semiconductor layer forming gas), and bulk layer 4b may be formed by introduction of another semiconductor layer forming gas (second semiconductor layer forming gas), and n-side buffer layer 4c may be formed by introduction of yet another semiconductor layer forming gas.

Disilane gas (Si₂H₆ gas) and the like may be employed as another semiconductor layer forming gas when mixed gas including silane gas (SiH₄ gas) and hydrogen gas (H₂ gas) is employed as semiconductor layer forming gas. When disilane gas (Si₂H₆ gas) is employed as another semiconductor layer forming gas, a film can be formed at high speed.

In this case, semiconductor layer forming gas is introduced into reaction chamber 70, and the semiconductor layer forming gas is allowed to generate a plasma discharge, so that p-side buffer layer 4 is formed on p-type layer 3. Next, in addition to semiconductor layer forming gas, another semiconductor layer forming gas is introduced into reaction chamber 70. Mixed gas including semiconductor layer forming gas and another semiconductor layer forming gas (upper semiconductor layer forming gas) is allowed to generate a plasma discharge, so that bulk layer 4b is formed so as to cover p-side buffer layer 4a.

Herein, when bulk layer 4b is formed, another semiconductor layer forming gas is preferably introduced into reaction chamber 70 in a state where introduction of semiconductor layer forming gas into reaction chamber 70 is not stopped even after the plasma discharge processing for forming p-side buffer layer 4a is terminated. After the plasma discharge processing for forming p-side buffer layer 4a is terminated, another semiconductor layer forming gas may be introduced into reaction chamber 70 while introduction of semiconductor layer forming gas into reaction chamber 70 is performed intermittently (with introduction/stopping at least once).

Similarly, in addition to another semiconductor layer forming gas, yet another semiconductor layer forming gas may be introduced into reaction chamber 70. Mixed gas including another semiconductor layer forming gas and yet another semiconductor layer forming gas is allowed to generate a plasma discharge to form n-side buffer layer 4c so as to cover bulk layer 4b.

Similarly, when n-side buffer layer 4c is formed, yet another semiconductor layer forming gas is preferably introduced into reaction chamber 70 in a state where introduction of another semiconductor layer forming gas into reaction chamber 70 is not stopped even after a plasma discharge processing for forming bulk layer 4b is terminated. After the plasma discharge processing for forming bulk layer 4b is terminated, yet another semiconductor layer forming gas may be introduced into reaction chamber 70 while introduction of another semiconductor layer forming gas into reaction chamber 70 is performed intermittently (with introduction/stopping at least once).

After p-side buffer layer 4a is formed, formation of bulk layer 4b is started without highly evacuating reaction chamber 70. After bulk layer 4b is formed, formation of n-side buffer layer 4c is started without highly evacuating reaction chamber 70. Energy and time for once highly evacuating reaction chamber 70 are not required, so that productivity is improved. This similarly applies to i-type layer 7.

In the method for manufacturing photoelectric conversion device 100 described above, n-type layer 5 is formed from substrate-side n-type layer 5a and backside n-type layer 5b by adjustment of SiH₄ gas flow rate control device 13 and/or H₂ gas flow rate control device 23 and/or PH₃/H₂ gas flow rate control device 33. As to n-type layer 5, substrate-side n-type layer 5a is formed by introduction of n-type impurity gas (first impurity gas) and backside n-type layer 5b is formed by introduction of another n-type impurity gas (second impurity gas).

In this case, n-type impurity gas (in addition to semiconductor layer forming gas for forming n-side buffer layer 4c) is introduced into reaction chamber 70. N-type layer forming gas (lower first conductivity type layer forming gas) including semiconductor layer forming gas and n-type impurity gas is allowed to generate a plasma discharge, so that substrate-side n-type layer 5a is formed on n-side buffer layer 4c.

Herein, when substrate-side n-type layer 5a is formed, n-type impurity gas is preferably introduced into reaction chamber 70 in a state where introduction of semiconductor layer forming gas into reaction chamber 70 is not stopped even after a plasma discharge processing for forming n-side buffer layer 4c is terminated. After the plasma discharge processing for forming n-side buffer layer 4c is terminated, n-type impurity gas may be introduced into reaction chamber 70 while introduction of semiconductor layer forming gas into reaction chamber 70 is performed intermittently (with introduction/stopping at least once).

Next, in addition to semiconductor layer forming gas and n-type impurity gas, another n-type impurity gas is introduced into reaction chamber 70. Another n-type layer forming gas (upper first conductivity type layer forming gas) including semiconductor layer forming gas, n-type impurity gas, and another n-type impurity gas is allowed to generate a plasma discharge to form back-side n-type layer 5b on substrate-side n-type layer 5b.

When n-type impurity gas is, for example, phosphine gas (PH₃ gas), another n-type impurity gas may be employed, such as nitrogen gas (N₂ gas), oxygen gas (O₂ gas), carbon dioxide gas (CO₂), or methane gas (CH₄ gas). When nitrogen gas (N2 gas), oxygen gas (O₂ gas), or carbon dioxide gas (CO₂) is employed as another n-type impurity gas, another n-type impurity gas may serve as n-type impurities and wide-gap impurities. When methane gas (CH₄ gas) is employed as another n-type impurity gas, another n-type impurity gas may serve as wide-gap impurities.

Similarly, when backside n-type layer 5b is formed, another n-type impurity gas is preferably introduced into reaction chamber 70 in a state where introduction of n-type impurity gas into reaction chamber 70 is not stopped even after a plasma discharge processing for forming substrate-side n-type layer 5a is terminated. After the plasma discharge processing for forming substrate-side n-type layer 5a is terminated, another n-type impurity gas may be introduced into reaction chamber 70 while introduction of n-type impurity gas into reaction chamber 70 is performed intermittently (with introduction/stopping at least once).

After substrate-side n-type layer 5a is formed, formation of backside n-type layer 5b is started without highly evacuating reaction chamber 70. Energy and time for once highly evacuating reaction chamber 70 are not required, so that productivity is improved.

### Second Embodiment

The present embodiment will be described based on, as another example of the method for manufacturing a semiconductor device, a method for manufacturing an inversely-staggered thin film transistor having a conductivity type layer (n-type layer (n⁺ a-Si layer)) deposited so as to cover a semiconductor layer (amorphous silicon layer). The inversely-staggered thin film transistor obtained by the method is an example of a switching semiconductor device having a thin film transistor.

(Inversely-Staggered Thin Film Transistor 300)

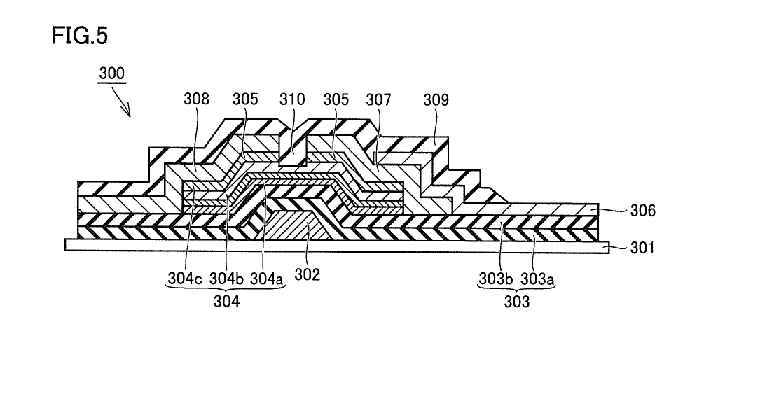

Referring to FIG. 5, an inversely-staggered thin film transistor 300 is configured by forming a gate electrode 302, a gate insulating film 303, an amorphous silicon layer 304, an amorphous n-type silicon layer 305 (hereinafter, referred to as “n⁺ a-Si layer 305”), a transparent electrode 306, a drain electrode 307, a source electrode 308, and a protective film 309 on a substrate 301.

Substrate 301 is made of glass and the like exhibiting an insulation property. Gate electrode 302 contains Cr (chromium), Mo (molybdenum), Ta (tantalum) alloy, Al (aluminum), or the like. Gate electrode 302 is electrically connected to gate interconnection (not illustrated). Gate insulating film 303 contains SiO₂ (silicon oxide), SiN_{X} (silicon nitride), or the like. Gate insulating film 303 in accordance with the present embodiment has a two-layer structure with lamination of a lower gate insulating film 303a and an upper gate insulating film 303b formed at a slower speed than lower gate insulating film 303a.

Amorphous silicon layer 304 serving as a transistor has a three-layer structure with sequential lamination of a first amorphous silicon layer 304a formed at the slowest speed, a second amorphous silicon layer 304b formed at a speed faster that of first amorphous silicon layer 304a, and a third amorphous silicon layer 304c formed at the highest speed. N⁺ a-Si layer 305 is an amorphous silicon layer containing an appropriate amount of n-type impurities and is formed to achieve a favorable ohmic contact between amorphous silicon layer 304 and drain electrode 307 and between amorphous silicon layer 304 and source electrode 308.

Drain electrode 307 and source electrode 308 are made of metal material such as Ti (titan), Ta (tantalum) or the like, or made of Al—Si alloy or the like. Transparent electrode 306 is, for example, an ITO (Indium Tin Oxide) layer and is in contact with drain electrode 307. When inversely-staggered thin film transistor 300 is employed in an active matrix liquid crystal display, transparent electrode 306 constitutes a pixel electrode. Protective film 309 includes, for example, SiN_{X} (silicon nitride) and the like and is provided to improve reliability of inversely-staggered thin film transistor 300.

(Plasma CVD Device 200)

As to a plasma CVD device 200 used for manufacturing inversely-staggered thin film transistor 300, a configuration is substantially the same as plasma CVD device 200 (refer to FIG. 2) in the first embodiment described above except for the difference in a type of gas to be introduced from a gas introduction system. Therefore, detailed description will not be repeated.

(Method for Manufacturing Inversely-staggered Thin Film Transistor 300)

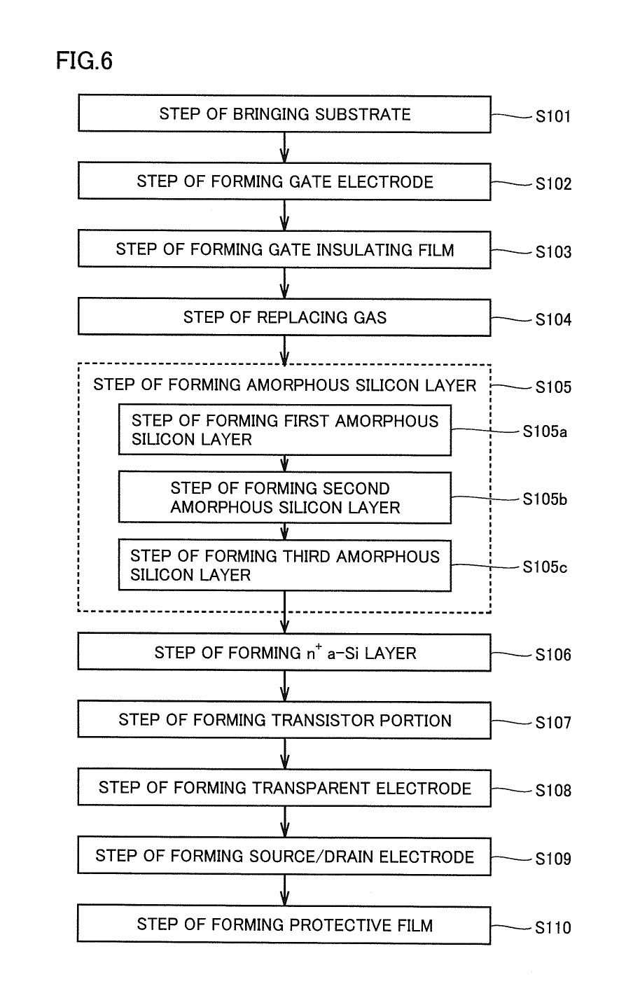

Referring to FIGS. 5 and 6, the method for manufacturing inversely-staggered thin film transistor 300 (steps S101-S110) will be described in order.

(Step S101: Step of bringing substrate, and Step S102: Step of Forming Gate Electrode)

Firstly, after substrate 301 is brought into reaction chamber 70 (refer to FIG. 2), gate electrode 302 is formed on substrate 301 in reaction chamber 70. When gate electrode 302 is formed, a sputtering method or the like is used to form a conductive film of Cr (chromium) or the like on a surface of substrate 301. Thereafter, an etching method or the like is used to perform patterning on a conductive film to have a predetermined shape, so that gate electrode 302 is formed.

Substrate 301 having gate electrode 302 formed by another device (not illustrated) may be brought into reaction chamber 70 of plasma CVD device 200.

(Step S103: Step of Forming Gate Insulating Film)

Substrate 301 having gate electrode 302 formed thereon is heated in reaction chamber 70. Material gas used for deposition of gate insulating film 303 is introduced into reaction chamber 70. The introduced material gas includes, for example, silane gas (SiH₄ gas), hydrogen gas (H₂ gas), nitrogen gas (N₂ gas), and ammonium gas (NH₃ gas). In the state where the material gas is introduced into reaction chamber 70, the pressure in reaction chamber 70 is maintained substantially constant. Plasma is generated by supplying alternate current power to substrate 301, and the material gas is dissolved (disassociated) and diffused by a plasma discharge to form gate insulating film 303 so as to cover gate electrode 302.

As to gate insulating film 303 of the present embodiment, as shown in FIG. 5, after a lower gate insulating film 303a is formed, an upper gate insulating film 303b is formed on lower gate insulating film 303a. Lower gate insulating film 303a and upper gate insulating film 303b have different characteristics by changing deposition speeds. Lower gate insulating film 303a and upper gate insulating film 303b may be made of the same material or different materials.

Since upper gate insulating film 303b directly affects the smoothness of amorphous silicon layer 304 (first amorphous silicon layer 304a) to be laminated thereon, the surface of upper gate insulating film 303b is preferably formed to have a favorable smoothness. Since lower gate insulating film 303a also affects the smoothness of upper gate insulating film 303b significantly, the surface of lower gate insulating film 303a is preferably formed to have a favorable smoothness.

Upper gate insulating film 303b is deposited at a lower deposition speed than lower gate insulating film 303a, so that a film having a favorable smoothness can be formed. On the other hand, lower gate insulating film 303a is formed at a relatively higher deposition speed than that of upper gate insulating film 303b. Such configuration can ensure the smoothness of amorphous silicon layer 304 (first amorphous silicon layer 304a) formed on gate insulating film 303 and shorten the time required to form gate insulating film 303, thereby improving productivity of the method for manufacturing inversely-staggered thin film transistor 300. The deposition speeds of lower gate insulating film 303a and upper gate insulating film 303b can be changed by varying the introduction amount of material gas, a pressure of plasma CVD, power, or intervals of electrodes.

(Step S104: Step of Replacing Gas)

In reaction chamber 70, impurities introduced in steps S101-S103 remain. To reduce the concentration of impurities in reaction chamber 70, gas in reaction chamber 70 is replaced by replacement gas (step S104). The gas replacement is conducted by a method similar to that of step S3 in the first embodiment described above.

(Step S105: Step of Forming Amorphous Silicon Layer)

Next, amorphous silicon layer 304 is formed. Amorphous silicon layer 304 may be a completely undoped amorphous silicon layer, or a substantially amorphous silicon layer such as a weak p-type semiconductor layer or a weak n-type semiconductor layer containing a small amount of impurities. Amorphous silicon layer 304 in accordance with the present embodiment is configured by first amorphous silicon layer 304a, second amorphous silicon layer 304b, and third amorphous silicon layer 304c.

In step S105, semiconductor layer forming gas is introduced into reaction chamber 70, so that first amorphous silicon layer 304a of amorphous silicon layer 304 is formed (step S105a). The semiconductor layer forming gas to be introduced in this stage includes, for example, silane gas (SiH₄ gas), hydrogen gas (H₂ gas), and argon gas (Ar gas).

In the state where the semiconductor layer forming gas is introduced, the pressure in reaction chamber 70 is maintained substantially constant. Alternate current power is supplied to substrate 301 to generate plasma. Semiconductor layer forming gas is dissolved (disassociated) and diffused by a plasma discharge to form first amorphous silicon layer 304a so as to cover gate insulating film 303 (upper gate insulating film 303b).

Next, second amorphous silicon layer 304b is formed so as to cover first amorphous silicon layer 304a (step S105b). In the state of step S105a described above, a flow rate of hydrogen gas (H₂ gas) relative to silane gas (SiH₄ gas) is increased by adjustment of SiH₄ gas flow rate control device 13 and H₂ gas flow rate control device 23. Deposition of second amorphous silicon layer 304b is started such that the deposition speed of amorphous silicon layer 304 becomes faster as compared to the deposition speed of first amorphous silicon layer 304a.

Also in this stage, the pressure in reaction chamber 70 is maintained substantially constant in the state where exhaust valve 85 is opened. Semiconductor layer forming gas having a changed flow rate ratio (mixture ratio) is dissolved (disassociated) and diffused by plasma discharge to form second amorphous silicon layer 304b so as to cover first amorphous silicon layer 304a.

Next, third amorphous silicon layer 304c is formed so as to cover second amorphous silicon layer 304b (step S105c). In the state of step S105b, the flow rate of nitrogen gas (H₂ gas) relative to silane gas (SiH₄ gas) is further increased by adjustment of SiH₄ gas flow rate control device 13 and H₂ gas flow rate control device 23. Deposition of third amorphous silicon layer 304c is started such that the deposition speed of amorphous silicon layer 304 becomes faster as compared to the deposition speed of second amorphous silicon layer 304b.

In the state where the pressure in reaction chamber 70 is maintained substantially constant, semiconductor layer forming gas having a further changed flow rate ratio (mixture ratio) is dissolved (disassociated) and diffused by a plasma discharge to form third amorphous silicon layer 304c so as to cover second amorphous silicon layer 304b.

(Step S106: n⁺ a-Si Layer Forming Step)

After amorphous silicon layer 304 is formed, amorphous n-type silicon layer 305 (n^{|} a-Si layer 305) is formed on amorphous silicon layer 304 (third amorphous silicon layer 304c). In the state where silane gas (SiH₄ gas) and hydrogen gas (H₂ gas) as semiconductor layer forming gas is supplied to reaction chamber 70, n-type impurity gas in addition to semiconductor layer forming gas is introduced into reaction chamber 70. This n-type impurity gas includes phosphine gas (CH₃ gas). When introduction of n-type impurity gas is added, the introduction condition (flow rate, extra ratio) of silane gas (SiH₄ gas) and hydrogen gas (H₂ gas) semiconductor layer forming gas may be different from the condition for forming amorphous silicon layer 304 and the condition for forming n⁺ a-Si layer 305.

In this stage, when n⁺ a-Si layer 305 is formed, n-type impurity gas is preferably introduced into reaction chamber 70 in the state where introduction of semiconductor layer forming gas into reaction chamber 70 is not stopped even after a plasma discharge processing for forming amorphous silicon layer 304 (third amorphous silicon layer 304c) is terminated. After the plasma discharge processing for forming amorphous silicon layer 304 (third amorphous silicon layer 304c) is terminated, n-type impurity gas may be introduced into reaction chamber 70 is performed while introduction of semiconductor layer forming gas is introduced into reaction chamber 70 intermittently (with introduction/stopping at least once). Semiconductor layer forming gas and n-type impurity gas are mixed to produce n-type layer forming gas. In the state where the pressure in reaction chamber 70 is not reduced to an ultimate value even after the plasma discharge processing for forming amorphous silicon layer 304 (third amorphous silicon layer 304c) is terminated, a composition set value (atmosphere) of reaction chamber 70 is shifted from a composition of semiconductor layer forming gas (the state where semiconductor layer forming gas is dominant) to a composition of n-type layer forming gas (mixed gas of appropriate combination of n-type impurity gas and semiconductor layer forming gas) (the state where n-type layer forming gas is dominant).

The state (atmosphere) where semiconductor layer forming gas is dominant described herein is an atmosphere defined by a supply composition (set value) of semiconductor layer forming gas. The state (atmosphere) where n-type layer forming gas is dominant described herein is an atmosphere defined by a supply composition (set value) of n-type layer forming gas. The ultimate vacuum described herein is a state where substantially no (zero) flow rate of gas component from inside of reaction chamber 70 to outside of reaction chamber 70 by vacuum pump 87 is present. Further, the state where the pressure in reaction chamber 70 is not reduced to ultimate vacuum described herein is a state where the pressure in reaction chamber 70 is higher than ultimate vacuum.

In the state where semiconductor layer forming gas and n-type impurity gas are introduced into reaction chamber 70, the pressure in reaction chamber 70 is maintained substantially constant.

To allow the state where semiconductor layer forming gas is dominant to be shifted to the state where n-type layer forming gas is dominant in a shorter period of time, the introduction amount of silane gas (SiH₄ gas) and hydrogen gas (H₂ gas) may be reduced. When the introduction amount of semiconductor layer forming gas into reaction chamber 70 is reduced, the state (atmosphere) where semiconductor layer forming gas is dominant is an atmosphere defined by a supply composition of semiconductor layer forming gas immediately before formation of amorphous silicon layer 304 is completed. Supply of alternate current power may be stopped until the state where semiconductor layer forming gas is dominant is shifted to the state where n-type layer forming gas is dominant.

After the state where semiconductor layer forming gas is dominant is shifted to the state where n-type layer forming gas is dominant, plasma is generated by supplying alternate current power to substrate 301. N-type layer forming gas is dissolved (disassociation) and diffused by a plasma discharge to form n⁺ a-Si layer 305 so as to cover amorphous silicon layer 304 (third amorphous silicon layer 304c).

N⁺ a-Si layer 305 may employ a laminated structure having two or more layers may be employed similarly to substrate-side n-type layer 5a and backside n-type layer 5b in n-type layer 5 according to the first embodiment described above. N⁺ a-Si layer 305 may be formed with a plurality of n-type layers having different impurity concentrations by adjustment of SiH₄ gas flow rate control device 13 and/or H₂ gas flow rate control device 23 and/or PH₃/H2 gas flow rate control device 33. N⁺ a-Si layer 305 may be formed by lamination of n-type amorphous layer and n-type microcrystal layer, formed only by n-type amorphous layer, or formed only by n-type microcrystal layer.

When n⁺ a-Si layer 305 is formed by laminating a plurality of n-type layers having different impurity concentrations, or formed by laminating an n-type amorphous layer and an-type microcrystal layer, the state (atmosphere) where n-type layer forming gas is dominant is an atmosphere defined by an n-type layer forming gas supply composition (set value) at the time of starting formation of layer in contact with amorphous silicon layer 304 (third amorphous silicon layer 304c).

(Step S107: Step of Forming Transistor Section)

Next, in order to form a transistor section, a predetermined patterning method such as a photolithography method is used to process amorphous silicon layer 304 and n⁺ a-Si layer 305 to have an island-like shape.

(Step S108: Step of Forming Transparent Electrode)

An ITO film having a predetermined thickness is formed by a sputtering method, and transparent electrode 306 is formed by a patterning method.

(Step S109: Step of Forming Source/Drain Electrode)

Thereafter, on amorphous silicon layer 304 and n⁺ a-Si layer 305 formed to have an island-like shape, a conductive film is formed by a sputtering method or the like using metals such as Al (aluminum), Mo (molybdenum), and the like. Drain electrode 307 and source electrode 308 are formed by patterning the conductive film. N⁺ a-Si layer 305 corresponding to an upper portion of a channel portion (310) is removed by dry etching.

(Step S110: Step of Forming Protective Film)

In order to protect inversely-staggered thin film transistor 300, a protective film 309 having transparency and insulating performance is formed. With the steps described above, the steps of manufacturing inversely-staggered thin film transistor 300 according to the present embodiment is completed.

(Operation and Effect)

According to the method for manufacturing inversely-staggered thin film transistor 300 of the present embodiment, after amorphous silicon layer 304 is formed, formation of n⁺ a-Si layer 305 is started without highly evacuating reaction chamber 70. According to the method, energy and time for once highly evacuating before forming n^{|} a-Si layer 305 are not required. Therefore, productivity is improved.

According to the method for manufacturing inversely-staggered thin film transistor 300 of the present embodiment, semiconductor layer forming gas is present in reaction chamber 70 also in the step of forming n⁺ a-Si layer 305 after formation of amorphous silicon layer 304. When n⁺ a-Si layer 305 is formed, reaction chamber 70 is not highly evacuated. Therefore, moisture does not float and adhere to substrate 301 (amorphous silicon layer 304) subject to processing. Even when moisture adhering inside of reaction chamber 70 and on vacuum system floats in gas atmosphere of reaction chamber 70, moisture collides with semiconductor layer forming gas present in reaction chamber 70. Therefore, moisture is suppressed from reaching substrate 301 (amorphous silicon layer 304) subject to processing.

Therefore, according to the method for manufacturing inversely-staggered thin film transistor 300 of the present embodiment, presence of semiconductor layer forming gas in reaction chamber 70 also in the step of forming n⁺ a-Si layer 305 causes impurities such as moisture to be hardly mixed into n⁺ a-Si layer 305.

When amorphous silicon layer 304 is formed, the flow rate of hydrogen gas (H₂ gas) relative to silane gas (SiH₄ gas) is changed by adjustment of SiH₄ gas flow rate control device 13 and H₂ gas flow rate control device 23 to form first amorphous silicon layer 304a, second amorphous silicon layer 304b, and third amorphous silicon layer 304c. Since SiH₄ gas and H₂ gas are not opened or closed, durable time of these valves long.

The method for manufacturing inversely-staggered thin film transistor 300 according to the present embodiment is so-called single chamber type depositing each layer on the substrate 301 in a single reaction chamber 70. As compared to the so-called multi-chamber type or the like having a plurality of reaction chambers, equipment costs and running costs are smaller. According to the method for manufacturing inversely-staggered thin film transistor 300 of the present embodiment, a photoelectric conversion device can be obtained in a less expensive manner.

[Another Form of the Second Embodiment]

According to the method for manufacturing inversely-staggered thin film transistor 300 described above, amorphous silicon layer 304 is formed from first amorphous silicon layer 304a, second amorphous silicon layer 304b, and third amorphous silicon layer 304c. Amorphous silicon layer 304 may be formed from first amorphous silicon layer 304a (lower semiconductor layer) and second amorphous silicon layer 304b (upper semiconductor layer). Amorphous silicon layer 304 may be formed from second amorphous silicon layer 304b (lower semiconductor layer) and third amorphous silicon layer 304c (upper semiconductor layer).

According to the method for manufacturing inversely-staggered thin film transistor 300 described above, amorphous silicon layer 304 is formed at a deposition speed changed by adjustment of SiH₄ gas flow rate control device 13 and H₂ gas flow rate control device 23, and formed as first amorphous silicon layer 304a, second amorphous silicon layer 304b, and third amorphous silicon layer 304c. As to amorphous silicon layer 304, first amorphous silicon layer 304a may be formed by introduction of semiconductor layer forming gas (first semiconductor layer forming gas), and second amorphous silicon layer 304b may be formed by introduction of another semiconductor layer forming gas (second semiconductor layer forming gas), and third amorphous silicon layer 304c may be formed by introduction of yet another semiconductor layer forming gas.

In this case, first amorphous silicon layer 304a is formed on upper gate insulating film 303b by introducing semiconductor layer forming gas into reaction chamber 70 and allowing semiconductor layer forming gas to generate a plasma discharge. Next, in addition to semiconductor layer forming gas, another semiconductor layer forming gas is introduced into reaction chamber 70. Second amorphous silicon layer 304b is formed so as to cover first amorphous silicon layer 304a allowing mixed gas (upper semiconductor layer forming gas) formed from semiconductor layer forming gas and another semiconductor layer forming gas to generate a plasma discharge.

In this stage, when second amorphous silicon layer 304b is formed, another semiconductor layer forming gas is preferably introduced into reaction chamber 70 in a state where introduction of semiconductor layer forming gas into reaction chamber 70 is not stopped even after a plasma discharge processing for forming first amorphous silicon layer 304a is terminated. After the plasma discharge processing for forming first amorphous silicon layer 304a is terminated, another semiconductor layer forming gas may be introduced into reaction chamber 70 while introduction of semiconductor layer forming gas into reaction chamber 70 is performed intermittently (with introduction/stopping at least once).

Similarly, in addition to another semiconductor layer forming gas, yet another semiconductor layer forming gas is introduced into reaction chamber 70. Third amorphous silicon layer 304c is formed so as to cover second amorphous silicon layer 304b by allowing mixed gas formed from another semiconductor layer forming gas and yet another semiconductor layer forming gas.

In this stage, also when third amorphous silicon layer 304c is formed, yet another semiconductor layer forming gas is preferably introduced into reaction chamber 70 in a state where introduction of another semiconductor layer forming gas into reaction chamber 70 is not stopped even after the plasma discharge processing for forming second amorphous silicon layer 304b is terminated. After the plasma discharge processing for forming second amorphous silicon layer 304b is terminated, yet another semiconductor layer forming gas may be introduced into reaction chamber 70 while introduction of another semiconductor layer forming gas into reaction chamber 70 is performed intermittently (with introduction/stopping at least once).

After first amorphous silicon layer 304a is formed, formation of second amorphous silicon layer 304b is started without highly evacuating reaction chamber 70. After second amorphous silicon layer 304b is formed, formation of third amorphous silicon layer 304c is started without highly evacuating reaction chamber 70. Energy and time for once highly evacuating reaction chamber 70 are not required. Therefore, productivity is improved.

According to the method for manufacturing inversely-staggered thin film transistor 300 described above, n′ a-Si layer 305 may be formed at a deposition speed changed by adjustment of SiH₄ gas flow rate control device 13 and H₂ gas flow rate control device 23 as substrate-side a-Si layer and backside n⁺ a-Si layer, as described above. As to n⁺ a-Si layer 305, substrate-side n⁺ a-Si layer may be formed by introduction of n-type layer forming gas (first impurity gas), and backside n⁺ a-Si layer may be formed by introduction of another n-type layer forming gas (second impurity gas).

In this case, n-type impurity gas (in addition to semiconductor layer forming gas for forming third amorphous silicon layer 304c) is introduced into reaction chamber 70. Substrate-side n⁺ a-Si layer 305 is formed on third amorphous silicon layer 304c by allowing n-type layer forming gas (lower first conductivity type layer forming gas) including semiconductor layer forming gas and n-type impurity gas to generate a plasma discharge.

In this stage, when substrate-side n⁺ a-Si layer is formed, n-type impurity gas is preferably introduced into reaction chamber 70 in a state where introduction of semiconductor layer forming gas into reaction chamber 70 is not stopped even after a plasma discharge processing for forming third amorphous silicon layer 304c is terminated. After the plasma discharge processing for forming third amorphous silicon layer 304c is terminated, n-type impurity gas may be introduced into reaction chamber 70 while introduction of semiconductor layer forming gas into reaction chamber 70 is performed intermittently (with introduction/stopping at least once).

Next, in addition to semiconductor layer forming gas and n-type impurity gas, another n-type impurity gas is introduced into reaction chamber 70. Backside n′ a-Si layer is formed on substrate-side n′ a-Si layer by allowing another n-type layer forming gas (upper first conductivity type layer forming gas) including semiconductor layer forming gas, n-type impurity gas, and another n-type impurity gas to generate a plasma discharge.

In this stage, when backside n⁺ a-Si layer is formed, another n-type impurity gas is preferably introduced into reaction chamber 70 in a state where introduction of n-type impurity gas into reaction chamber 70 is not stopped even after a plasma discharge processing for forming substrate-side n⁺ a-Si layer is terminated. Another n-type impurity gas may be introduced into reaction chamber 70 while introduction of n-type impurity gas into reaction chamber 70 is performed intermittently (at least one time of introduction/stopping).

After the substrate-side n⁺ a-Si layer is formed, formation of backside n⁺ a-Si layer is started without highly evacuating reaction chamber 70. Energy and time for once highly evacuating reaction chamber 70 are not required. Therefore, productivity is improved.

Embodiments of the present invention has been described. It is to be understood that the embodiments disclosed herein are only by way of example, and not to be taken by way of limitation. The scope of the present invention is defined by the scope of claims, and is intended to include any modification within the scope and meaning equivalent to the terms of the claims.

### REFERENCE SIGNS LIST

1 transparent substrate; 2 transparent conductive film; 4 i-type layer; 4a, 7a p-side buffer layer; 4b, 7b bulk layer; 4c, 7c n-side buffer layer; 5, 8 n-type layer; 5a substrate-side n-type layer; 5b backside n-type layer; 6 p-type layer; 7 source electrode; 8 drain electrode; 9 backside transparent conductive film; 10 backside metal electrode; 11, 15, 21, 25, 31, 35, 41, 45, 51, 55, 61, 65 valve; 13 SiH₄ gas flow rate control device; 23 H₂ gas flow rate control device; 33 PH₃/H₂ gas flow rate control device; 43 B₂H₆/H₂ flow rate control device; 53 CH₄ gas flow rate control device; 63 GeH₄/H₂ gas flow rate control device; 70 reaction chamber; 71 cathode electrode; 73 matching box; 75 high frequency power supply; 81 anode electrode; 83 pressure adjusting valve; 85 exhaust valve; 87 vacuum pump; 90 gas introduction system; 92 gas introduction section; 100 photoelectric conversion device; 100A, 100B photoelectric conversion layer; 200 plasma CVD device; 300 inversely-staggered thin film transistor; 301 substrate; 302 gate electrode; 303 gate insulating film; 303b upper gate insulating film; 303a lower gate insulating film; 304 amorphous silicon layer; 304a first amorphous silicon layer; 304b second amorphous silicon layer; 304c third amorphous silicon layer, 305 amorphous n-type silicon layer; 306 transparent electrode; 307 drain electrode; 308 source electrode; 309 protective film; 310 channel portion; S1-S14, S6a, S6b, S6c, S7a, S7b, S101-S110, S105a, S105b, S105c step.

1. A method for manufacturing a semiconductor device by using a plasma CVD method to deposit a conductivity type layer so as to cover a semiconductor layer, the method comprising the steps of:
forming said semiconductor layer on a predetermined layer by introducing semiconductor layer forming gas into a reaction chamber and allowing said semiconductor layer forming gas to generate a plasma discharge; and
forming a first conductivity type layer of a first conductivity type so as to cover said semiconductor layer by introducing impurity gas in addition to said semiconductor layer forming gas into said reaction chamber and allowing first conductivity type layer forming gas including said semiconductor layer forming gas and said impurity gas to generate a plasma discharge, and
in said step of forming said first conductivity type layer, a composition set value of gas supplied to said reaction chamber is shifted from a composition of said semiconductor layer forming gas to a composition of said first conductivity type layer forming gas in a state where a pressure in said reaction chamber is not reduced to ultimate vacuum even after a plasma discharge processing for forming said semiconductor layer is terminated.

2. The method for manufacturing a semiconductor device according to claim 1, wherein in said step of forming said first conductivity type layer, said impurity gas is introduced into said reaction chamber in a state where introduction of said semiconductor layer forming gas into said reaction chamber is not stopped even after the plasma discharge processing for forming said semiconductor layer is terminated.

3. The method for manufacturing a semiconductor device according claim 1, wherein
said first conductivity type layer includes a lower first conductivity type layer (5a) of a first conductivity type and an upper first conductivity type layer of the first conductivity type, and
said impurity gas includes first impurity gas for forming said lower first conductivity type layer and second impurity gas for forming said upper first conductivity type layer, and
said step of forming said first conductivity type layer includes the steps of:
forming said lower first conductivity type layer so as to cover said semiconductor layer by introducing said first impurity gas in addition to said semiconductor layer forming gas into said reaction chamber and allowing lower first conductivity type layer forming gas including said semiconductor layer forming gas and said first impurity gas to generate a plasma discharge; and
forming said upper first conductivity type layer so as to cover said lower first conductivity type layer by introducing said second impurity gas in addition to said semiconductor layer forming gas and said first impurity gas into said reaction chamber and allowing upper first conductivity type layer forming gas including said semiconductor layer forming gas, said first impurity gas, and said second impurity gas to generate a plasma discharge, and
in said step of forming said upper first conductivity type layer, a composition set value of gas supplied to said reaction chamber is shifted from a composition of said lower first conductivity type layer forming gas to a composition of said second impurity gas in a state where a pressure in said reaction chamber is not reduced to ultimate vacuum even after a plasma discharge processing for forming said lower first conductivity type layer is terminated.

4. The method for manufacturing a semiconductor device according to claim 1, wherein
said first conductivity type layer includes a lower first conductivity type layer of a first conductivity type and an upper first conductivity type layer of the first conductivity type, and
said step of forming said first conductivity type layer includes the steps of:
forming said lower first conductivity type layer so as to cover said semiconductor layer by introducing said impurity gas in addition to said semiconductor layer forming gas into said reaction chamber for a predetermined time period and allowing lower first conductivity type layer forming gas including said semiconductor layer forming gas and said impurity gas to generate a plasma discharge, and
forming said upper first conductivity type layer so as to cover said lower first conductivity type layer by allowing upper first conductivity type layer forming gas including said impurity gas and said semiconductor layer forming gas, with an introduction amount ratio changed by modifying an introduction amount ratio of said impurity gas relative to an introduction amount of said semiconductor layer forming gas after forming said lower first conductivity type layer, to generate a plasma discharge, and
in said step of forming said upper first conductivity type layer, a composition set value of gas supplied to said reaction chamber is shifted from a composition of said lower first conductivity type layer forming gas to a composition of said upper first conductivity type layer forming gas in a state where a pressure in said reaction chamber is not reduced to ultimate vacuum even after a plasma discharge processing for forming said lower first conductivity type layer is terminated.

5. The method for manufacturing a semiconductor device according to claim 1, wherein
said semiconductor layer includes a lower semiconductor layer and an upper semiconductor layer, and
said semiconductor layer forming gas includes first semiconductor layer forming gas for forming said lower semiconductor layer and second semiconductor layer forming gas for forming said upper semiconductor layer, and
said step of forming said semiconductor layer includes the steps of:
forming said lower semiconductor layer, on said predetermined layer by introducing said first semiconductor layer forming gas into said reaction chamber and allowing said first semiconductor layer forming gas to generate a plasma discharge; and
forming said upper semiconductor layer, so as to cover said lower semiconductor layer by introducing said second semiconductor layer forming gas in addition to said first semiconductor layer forming gas into said reaction chamber and allowing upper semiconductor layer forming gas including said first semiconductor layer forming gas and said second semiconductor layer forming gas to generate a plasma discharge, and
in said step of forming said upper semiconductor layer, a composition set value of gas supplied to said reaction chamber is shifted from a composition of said first semiconductor layer forming gas to a composition of said upper semiconductor layer forming gas in a state where a pressure in said reaction chamber is not reduced to ultimate vacuum even after a plasma discharge processing for forming said lower semiconductor layer is terminated.

6. The method for manufacturing a semiconductor device according to claim 1, wherein
said semiconductor layer includes a lower semiconductor layer and an upper semiconductor layer, and
said step of forming said semiconductor layer includes the steps of:
forming said lower semiconductor layer on said predetermined layer by introducing said semiconductor layer forming gas into said reaction chamber for another predetermined period of time, and allowing said semiconductor layer forming gas to generate a plasma discharge; and
forming said upper semiconductor layer so as to cover said lower semiconductor layer by allowing said semiconductor layer forming gas, with an introduction amount changed by modifying an introduction of said semiconductor layer forming gas after forming said lower semiconductor layer, to generate a plasma discharge, and
in said step of forming said upper semiconductor layer, a composition set value of gas supplied to said reaction chamber is shifted from a composition of said semiconductor layer forming gas for forming said lower semiconductor layer to a composition of said semiconductor layer forming gas for forming said upper semiconductor layer in a state where a pressure in said reaction chamber is not reduced to ultimate vacuum even after a plasma discharge processing for forming said lower semiconductor layer is terminated.

7. The method for manufacturing a semiconductor device according to claim 1, wherein
said semiconductor layer includes a lower semiconductor layer and an upper semiconductor layer and
said semiconductor layer forming gas includes semiconductor material gas and diluted gas, and
said step of forming said semiconductor layer includes the steps of:
forming said lower semiconductor layer on said predetermined layer by introducing said semiconductor layer forming gas into said reaction chamber for another predetermined period of time and allowing said semiconductor layer forming gas to generate a plasma discharge; and
forming said upper semiconductor layer so as to cover said lower semiconductor layer by allowing said semiconductor layer forming gas, with an introduction amount ratio changed by modifying an introduction amount ratio of said semiconductor material gas and said diluted gas in said semiconductor layer forming gas after forming said lower semiconductor layer, to generate a plasma discharge, and
in said step of forming said upper semiconductor layer, a composition set value of gas supplied to said reaction chamber is shifted from a composition of said semiconductor layer forming gas for forming said lower semiconductor layer to a composition of said semiconductor layer forming gas for forming said upper semiconductor layer in a state where a pressure in said reaction chamber is not reduced to ultimate vacuum even after a plasma discharge processing for forming said lower semiconductor layer is terminated.

8. The method for manufacturing a semiconductor device according to claim 1, wherein an introduction amount of said semiconductor layer forming gas into said reaction chamber is reduced to a predetermined flow rate after forming said semiconductor layer.

9. The method for manufacturing a semiconductor device according to claim 1, further comprising the step of forming a second conductivity type layer of a second conductivity type on another predetermined layer by supplying another impurity gas onto said another predetermined layer.

10. The method for manufacturing a semiconductor device according to claim 9, wherein said another impurity gas is introduced into said reaction chamber, and said second conductivity type layer is formed in said reaction chamber.

11. The method for manufacturing a semiconductor device according to claim 1, wherein said semiconductor device is a photoelectric conversion device.

12. The method for manufacturing a semiconductor device according to claim 1, wherein said semiconductor device is a switching semiconductor device having a thin film transistor.
